(19) United States
(12) Patent Application Publication
(10) Pub. No.: US 2025/0370652 A1
(43) Pub. Date: Dec. 4, 2025

(54) MEMORY DEVICES, MEMORY CONTROLLERS, MEMORY SYSTEMS, AND OPERATION METHODS THEREOF

(71) Applicant: YANGTZE MEMORY TECHNOLOGIES CO., LTD., Wuhan (CN)

(72) Inventors: Lu Guo, Wuhan (CN); Boxuan Cheng, Wuhan (CN)

(21) Appl. No.: 18/741,120

(22) Filed: Jun. 12, 2024

Related U.S. Application Data
(63) Continuation of application No. PCT/CN2024/095937, filed on May 29, 2024.

(51) Int. Cl. G06F 3/06

(52) U.S. Cl. CPC G06F 3/0655; G06F 3/0604; G06F 3/0679

(57) ABSTRACT

In certain aspects, a memory system is disclosed. The memory system includes a non-volatile memory device configured to store data and a memory controller coupled to the non-volatile memory device. The memory controller is configured to determine one or more combined read conditions based on passed read retry conditions associated with historical read retry operations. The memory controller is further configured to control the non-volatile memory device to perform a read operation based on the one or more combined read conditions.

### CROSS-REFERENCE TO RELATED APPLICATIONS

This application is a continuation of International Application No. PCT/CN2024/095937, filed on May 29, 2024, which is hereby incorporated by reference in its entirety.

### BACKGROUND

The present disclosure relates to a memory device, a memory controller, a memory system including the memory device and the memory controller, and operation methods thereof.

Non-volatile storage devices such as solid-state drives (SSDs), non-volatile memory express (NVMe), embedded multimedia cards (eMMCs), and universal flash storage (UFS) devices, etc., have gained significant popularity in recent years due to their numerous advantages over traditional hard disk drives (HDDs), such as faster read and write speed, durability and reliability, reduced power consumption, silent operation, and smaller form factors. For example, non-volatile storage devices such as SSDs may use NAND Flash memory for non-volatile storage. Various operations can be performed by NAND Flash memory, such as read, program (write), and erase. For NAND Flash memory, an erase operation can be performed at the block level, and a program operation or a read operation can be performed at the page level.

### SUMMARY

In one aspect, a memory system is disclosed. The memory system includes a non-volatile memory device configured to store data and a memory controller coupled to the non-volatile memory device. The memory controller is configured to determine one or more combined read conditions based on passed read retry conditions associated with historical read retry operations. The memory controller is further configured to control the non-volatile memory device to perform a read operation based on the one or more combined read conditions.

In some implementations, the historical read retry operations include passed read retry operations each of which reads out corresponding data from the non-volatile memory device successfully using at least one of the passed read retry conditions.

In some implementations, the non-volatile memory device includes memory cells, and each of the memory cells is configured to store at least two bits, the at least two bits respectively corresponding to at least two pages.

In some implementations, the memory controller is further configured to record the passed read retry conditions associated with the historical read retry operations.

In some implementations, to record the passed read retry conditions associated with the historical read retry operations, the memory controller is further configured to record one or more passed read retry conditions for each historical read retry operation. Each of the one or more passed read retry conditions includes a read retry condition from a read retry table and is used to read out at least one of the at least two pages successfully in the historical read retry operation.

In some implementations, the at least two pages include at least a first page and a second page. The one or more passed read retry conditions include a first passed read retry condition for the first page and a second passed read retry condition for the second page. The first passed read retry condition includes one or more first read parameters used to read out the first page successfully in the historical read retry operation. The second passed read retry condition includes one or more second read parameters used to read out the second page successfully in the historical read retry operation.

In some implementations, each of the one or more first read parameters and the one or more second read parameters includes a read voltage or a read voltage offset.

In some implementations, the one or more combined read conditions include a first combined read condition. To determine the one or more combined read conditions, the memory controller is further configured to determine optimal read retry conditions for the at least two pages, respectively, at least by: for each page from the at least two pages, determining an optimal read retry condition from the passed read retry conditions. The optimal read retry condition includes a passed read retry condition having a first highest success count to read out the page in the historical read retry operations. The memory controller is further configured to combine the optimal read retry conditions to generate the first combined read condition based on the at least two pages.

In some implementations, the at least two pages include at least a first page and a second page. The optimal read retry conditions include a first optimal read retry condition for the first page and a second optimal read retry condition for the second page. The first combined read condition includes one or more first read parameters from the first optimal read retry condition for the first page and one or more second read parameters from the second optimal read retry condition for the second page.

In some implementations, the one or more combined read conditions further include a second combined read condition. To determine the one or more combined read conditions, the memory controller is further configured to determine sub-optimal read retry conditions for the at least two pages, respectively, at least by: for each page from the at least two pages, determining a sub-optimal read retry condition from the passed read retry conditions. The sub-optimal read retry condition includes a passed read retry condition having a second highest success count to read out the page in the historical read retry operations. The memory controller is further configured to combine the sub-optimal read retry conditions to generate the second combined read condition based on the at least two pages.

In some implementations, to control the non-volatile memory device to perform the read operation based on the one or more combined read conditions, the memory controller is further configured to: select a first combined read condition from the one or more combined read conditions; and control the non-volatile memory device to perform the read operation based on the first combined read condition.

In some implementations, the memory controller is further configured to: determine that the read operation based on the first combined read condition fails; determine that a count of combined read conditions selected to perform the read operation is smaller than a threshold; select a second combined read condition from the one or more combined read conditions; and control the non-volatile memory device to perform the read operation based on the second combined read condition.

In some implementations, the memory controller is further configured to: determine that the read operation on the non-volatile memory device based on the one or more combined read conditions fails or a count of combined read conditions selected to perform the read operation reaches a threshold; control the non-volatile memory device to perform a read retry operation based on a read retry table; and update the one or more combined read conditions based on a result of the read retry operation.

In some implementations, the memory controller is further configured to store the one or more combined read conditions in the non-volatile memory device responsive to power off.

In some implementations, each of the one or more combined read conditions includes read parameters from at least two different passed read retry conditions.

In some implementations, the at least two pages include a first page and a second page. Each of the one or more combined read conditions includes: one or more read parameters from a first one of the passed read retry conditions for the first page; and one or more read parameters from a second one of the passed read retry conditions for the second page.

In another aspect, a memory controller is disclosed. The memory controller includes a memory configured to store instructions and a processor coupled to the memory and configured to execute the instructions to perform a process. The process includes determining one or more combined read conditions based on passed read retry conditions associated with historical read retry operations on a non-volatile memory device. The process further includes controlling the non-volatile memory device to perform a read operation based on the one or more combined read conditions.

In some implementations, the historical read retry operations include passed read retry operations each of which reads out corresponding data from the non-volatile memory device successfully using at least one of the passed read retry conditions.

In some implementations, the non-volatile memory device includes memory cells, and each of the memory cells is configured to store at least two bits, the at least two bits respectively corresponding to at least two pages.

In some implementations, the process further includes recording the passed read retry conditions associated with the historical read retry operations.

In some implementations, to record the passed read retry conditions associated with the historical read retry operations, the processor is further configured to record one or more passed read retry conditions for each historical read retry operation. Each of the one or more passed read retry conditions includes a read retry condition from a read retry table and is used to read out at least one of the at least two pages successfully in the historical read retry operation.

In some implementations, the at least two pages include at least a first page and a second page. The one or more passed read retry conditions include a first passed read retry condition for the first page and a second passed read retry condition for the second page. The first passed read retry condition includes one or more first read parameters used to read out the first page successfully in the historical read retry operation. The second passed read retry condition includes one or more second read parameters used to read out the second page successfully in the historical read retry operation.

In some implementations, each of the one or more first read parameters and the one or more second read parameters includes a read voltage or a read voltage offset.

In some implementations, the one or more combined read conditions include a first combined read condition. To determine the one or more combined read conditions, the processor is further configured to determine optimal read retry conditions for the at least two pages, respectively, at least by: for each page from the at least two pages, determining an optimal read retry condition from the passed read retry conditions. The optimal read retry condition includes a passed read retry condition having a first highest success count to read out the page in the historical read retry operations. The processor is further configured to combine the optimal read retry conditions to generate the first combined read condition based on the at least two pages.

In some implementations, the at least two pages include at least a first page and a second page. The optimal read retry conditions include a first optimal read retry condition for the first page and a second optimal read retry condition for the second page. The first combined read condition includes one or more first read parameters from the first optimal read retry condition for the first page and one or more second read parameters from the second optimal read retry condition for the second page.

In some implementations, the one or more combined read conditions further include a second combined read condition. To determine the one or more combined read conditions, the processor is further configured to determine sub-optimal read retry conditions for the at least two pages, respectively, at least by: for each page from the at least two pages, determining a sub-optimal read retry condition from the passed read retry conditions. The sub-optimal read retry condition includes a passed read retry condition having a second highest success count to read out the page in the historical read retry operations. The processor is further configured to combine the sub-optimal read retry conditions to generate the second combined read condition based on the at least two pages.

In some implementations, to control the non-volatile memory device to perform the read operation based on the one or more combined read conditions, the processor is further configured to: select a first combined read condition from the one or more combined read conditions; and control the non-volatile memory device to perform the read operation based on the first combined read condition.

In some implementations, the process further includes: determining that the read operation based on the first combined read condition fails; determining that a count of combined read conditions selected to perform the read operation is smaller than a threshold; selecting a second combined read condition from the one or more combined read conditions; and controlling the non-volatile memory device to perform the read operation based on the second combined read condition.

In some implementations, the process further includes: determining that the read operation on the non-volatile memory device based on the one or more combined read conditions fails or a count of combined read conditions selected to perform the read operation reaches a threshold; controlling the non-volatile memory device to perform a read retry operation based on a read retry table; and updating the one or more combined read conditions based on a result of the read retry operation.

In some implementations, the memory controller is further configured to store the one or more combined read conditions in the non-volatile memory device responsive to power off.

In some implementations, each of the one or more combined read conditions includes read parameters from at least two different passed read retry conditions.

In some implementations, the at least two pages include a first page and a second page. Each of the one or more combined read conditions includes: one or more read parameters from a first one of the passed read retry conditions for the first page; and one or more read parameters from a second one of the passed read retry conditions for the second page.

In still another aspect, a method of operating a memory controller is disclosed. The method includes determining one or more combined read conditions based on passed read retry conditions associated with historical read retry operations on a non-volatile memory device. The method further includes controlling the non-volatile memory device to perform a read operation based on the one or more combined read conditions.

In some implementations, the historical read retry operations include passed read retry operations each of which reads out corresponding data from the non-volatile memory device successfully using at least one of the passed read retry conditions.

In some implementations, the non-volatile memory device includes memory cells, and each of the memory cells is configured to store at least two bits, the at least two bits respectively corresponding to at least two pages.

In some implementations, the method further includes recording the passed read retry conditions associated with the historical read retry operations.

In some implementations, recording the passed read retry conditions associated with the historical read retry operations includes recording one or more passed read retry conditions for each historical read retry operation. Each of the one or more passed read retry conditions includes a read retry condition from a read retry table and is used to read out at least one of the at least two pages successfully in the historical read retry operation.

In some implementations, the at least two pages include at least a first page and a second page. The one or more passed read retry conditions include a first passed read retry condition for the first page and a second passed read retry condition for the second page. The first passed read retry condition includes one or more first read parameters used to read out the first page successfully in the historical read retry operation. The second passed read retry condition includes one or more second read parameters used to read out the second page successfully in the historical read retry operation.

In some implementations, each of the one or more first read parameters and the one or more second read parameters includes a read voltage or a read voltage offset.

In some implementations, the one or more combined read conditions include a first combined read condition. Determining the one or more combined read conditions includes determining optimal read retry conditions for the at least two pages, respectively, at least by: for each page from the at least two pages, determining an optimal read retry condition from the passed read retry conditions. The optimal read retry condition includes a passed read retry condition having a first highest success count to read out the page in the historical read retry operations. Determining the one or more combined read conditions further includes combining the optimal read retry conditions to generate the first combined read condition based on the at least two pages.

In some implementations, the at least two pages include at least a first page and a second page. The optimal read retry conditions include a first optimal read retry condition for the first page and a second optimal read retry condition for the second page. The first combined read condition includes one or more first read parameters from the first optimal read retry condition for the first page and one or more second read parameters from the second optimal read retry condition for the second page.

In some implementations, controlling the non-volatile memory device to perform the read operation based on the one or more combined read conditions includes: selecting a first combined read condition from the one or more combined read conditions; and controlling the non-volatile memory device to perform the read operation based on the first combined read condition.

In some implementations, the method further includes: determining that the read operation based on the first combined read condition fails; determining that a count of combined read conditions selected to perform the read operation is smaller than a threshold; selecting a second combined read condition from the one or more combined read conditions; and controlling the non-volatile memory device to perform the read operation based on the second combined read condition.

In yet another aspect, a non-transitory computer-readable storage medium including instructions is disclosed. The instructions, when executed by a processing device, cause the processing device to perform a method including: determining one or more combined read conditions based on passed read retry conditions associated with historical read retry operations on a non-volatile memory device; and controlling the non-volatile memory device to perform a read operation based on the one or more combined read conditions.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of a memory card having a memory device, according to some aspects of the present disclosure.

FIG. 2B illustrates a diagram of a solid-state drive (SSD) having a memory device, according to some aspects of the present disclosure.

FIG. 3 illustrates another block diagram of a system having a memory device, according to some aspects of the present disclosure.

FIG. 4 illustrates a schematic diagram of a memory device including peripheral circuits, according to some aspects of the present disclosure.

FIG. 5A illustrates a block diagram of a memory device including a memory cell array and peripheral circuits, according to some aspects of the present disclosure.

FIG. 5B illustrates read voltages of a triple-level cell (TLC), according to some aspects of the present disclosure.

FIG. 5C illustrates an example read retry table for a TLC memory cell, according to some aspects of the present disclosure.

FIG. 5D illustrates read voltages of a quad-level cell (QLC), according to some aspects of the present disclosure.

FIG. 5E illustrates an example read retry table for a QLC memory cell, according to some aspects of the present disclosure.

FIG. 6 illustrates a flowchart of a method for operating a memory controller, according to some examples of the present disclosure.

FIG. 7 illustrates a flowchart of a method for operating a memory controller, according to some aspects of the present disclosure.

FIG. 8 illustrates a flowchart of another method for operating a memory controller, according to some aspects of the present disclosure.

FIG. 9 illustrates a flowchart of a method for performing a read retry operation based on a read retry table, according to some aspects of the present disclosure.

FIGS. 10A-10C illustrate a generation of combined read conditions for a TLC memory device, according to some aspects of the present disclosure.

FIGS. 10D-10E illustrate a generation of combined read conditions for a QLC memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

In a non-volatile memory device, as the multi-bit per memory cell storage architecture emerges and becomes more popular in the industry, read margins become narrower. The memory device is more vulnerable to noises, program/read disturbances, coupling issues, charge loss, etc. Thus, more read errors may occur when a read operation is performed on the memory device. For example, the multi-level cell (MLC) technology significantly reduces read margins between different threshold voltage (Vth) levels used to store multiple bits in a single memory cell. Vth levels of the memory cells may shift beyond the read voltages (Vrd), resulting in more read errors. A read voltage may also be referred to as a read reference voltage (Vref), i.e., a voltage used to distinguish Vth levels of memory cells. In another example, time and temperature may hinder data retention (DR) in a memory device. Increased time and/or temperature may cause a memory device to wear more quickly and lose data (i.e., data retention loss). Errors, such as those caused by the retention loss, may be corrected, and the memory device may attempt to correct future errors.

Read retry and adjustments of read voltages may be one way to correct errors. A read retry operation can be performed by adjusting the read voltages of the memory device. However, if a large number of read retry operations are performed, the performance of the memory device may degrade significantly due to the read latency introduced by the multiple read retry steps that read a target page repeatedly with adjusted read voltages. For example, after data retention, it may take a relatively long time to read an SSD of an electronic product since a large number of read retry operations may be performed to correct errors caused by the data retention. As a result, the startup time of the electronic device is long (e.g., the out-of-the-box experience (OOBE) is long), leading to a downgrade in the use experience of the electronic device.

To address one or more of the aforementioned issues, the present disclosure introduces an improved read scheme that can optimize the use of a read retry table to improve the read performance of a memory device. Specifically, passed read retry conditions associated with historical read retry operations can be recorded, so that one or more combined read conditions can be determined based on the passed read retry conditions. For example, the passed read retry conditions can be recorded and processed based on different page types, and then, a combined read condition is generated to include a corresponding optimal read retry condition for each page. The combined read condition is applicable for reading all the different pages since it includes optimal read retry conditions for all the different pages, respectively. By applying the combined read conditions in a read operation, the number of the read retries (e.g., a read retry count) can be reduced greatly. For example, when reading a 256G memory device, the read retry count can be reduced from thousands of read retries to hundreds of read retries. As a result, the read performance of the memory device is improved.

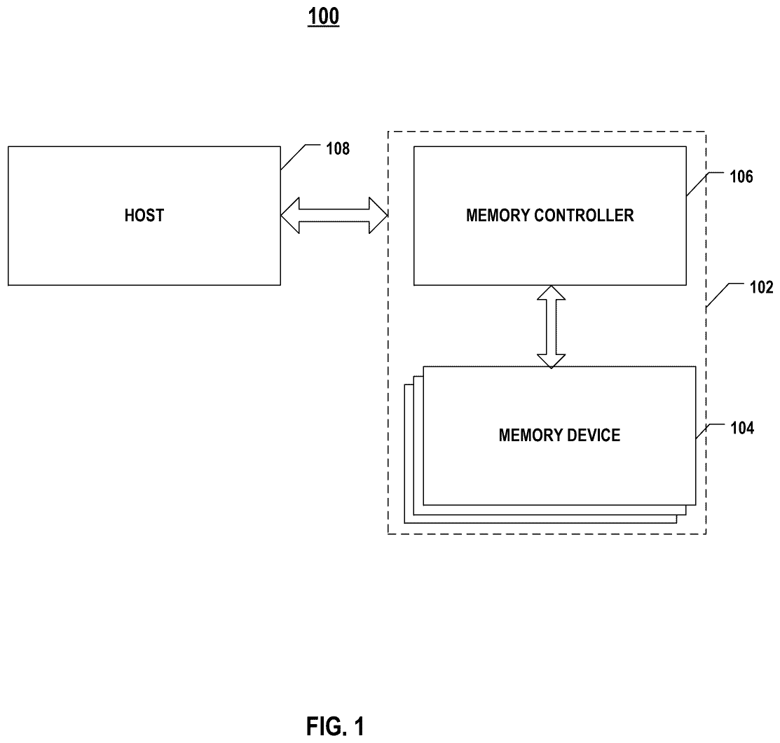

FIG. 1 illustrates a block diagram of a system 100 including a memory system 102, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data (a.k.a. user data or host data) to or from memory system 102. Memory system 102 can be a storage product integrating memory controller 106 and one or more memory devices 104, such as an SSD.

Memory devices 104 can be any memory devices disclosed in the present disclosure, including non-volatile memory devices, such as NAND Flash memory devices. In some implementations, memory device 104 also includes one or more volatile memory devices, such as dynamic random-access memory (DRAM) devices or static random-access memory (SRAM) devices.

Memory controller 106 is operatively coupled to memory devices 104 and host 108 and is configured to control memory devices 104, according to some implementations. Memory controller 106 can manage the data stored in memory devices 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment with SSDs or embedded multimedia card (eMMCs) used as data storage for mobile devices, such as smartphones, tablets, laptop computers, etc., and enterprise storage arrays. Memory controller 106 can be configured to control operations of memory devices 104, such as read, program/write, and/or erase operations. Memory controller 106 can also be configured to manage various functions with respect to the data stored or to be stored in memory devices 104 including, but not limited to bad-block management, garbage collection, logical-to-physical (L2P) address conversion, wear-leveling, etc. In some implementations, memory controller 106 is further configured to process error correction codes (ECCs) with respect to the data read from or written to memory devices 104. Any other suitable functions may be performed by memory controller 106 as well, for example, formatting memory devices 104. Memory controller 106 can communicate with an external device (e.g., host 108) according to a particular communication protocol. For example, memory controller 106 may communicate with the external device through at least one of various interface protocols, such as a non-volatile memory express (NVMe) protocol, an NVMe-over-fabrics (NVMe-oF) protocol, a PCI-express (PCI-E) protocol, a universal serial bus (USB) protocol, a multimedia card (MMC) protocol, a peripheral component interconnection (PCI) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

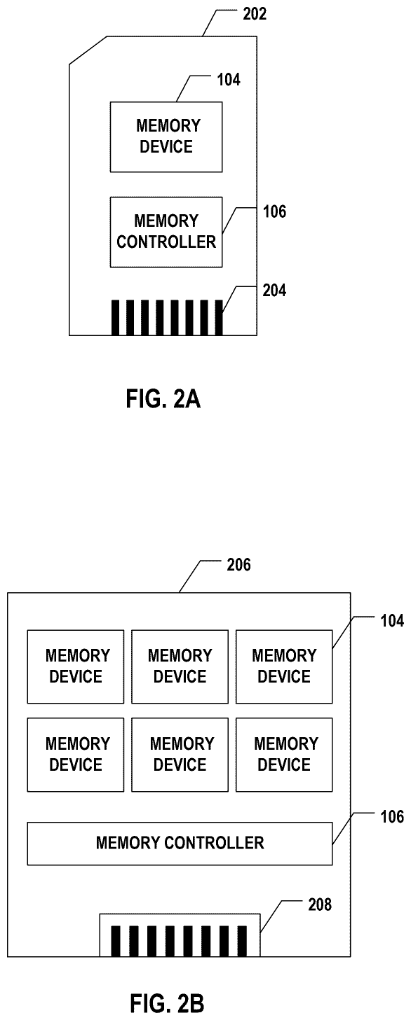

Memory controller 106 and one or more memory devices 104 can be integrated into various types of storage devices, for example, being included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 1). In another example as shown in FIG. 2B, memory controller 106 and multiple memory devices 104 may be integrated into an SSD 206. SSD 206 can further include an SSD connector 208 coupling SSD 206 with a host (e.g., host 108 in FIG. 1). In some implementations, the storage capacity and/or the operation speed of SSD 206 is greater than those of memory card 202. In some implementations, memory system 102 is implemented as an SSD 206 that includes both non-volatile memory devices and volatile memory devices as memory devices 104, such as an enterprise SSD.

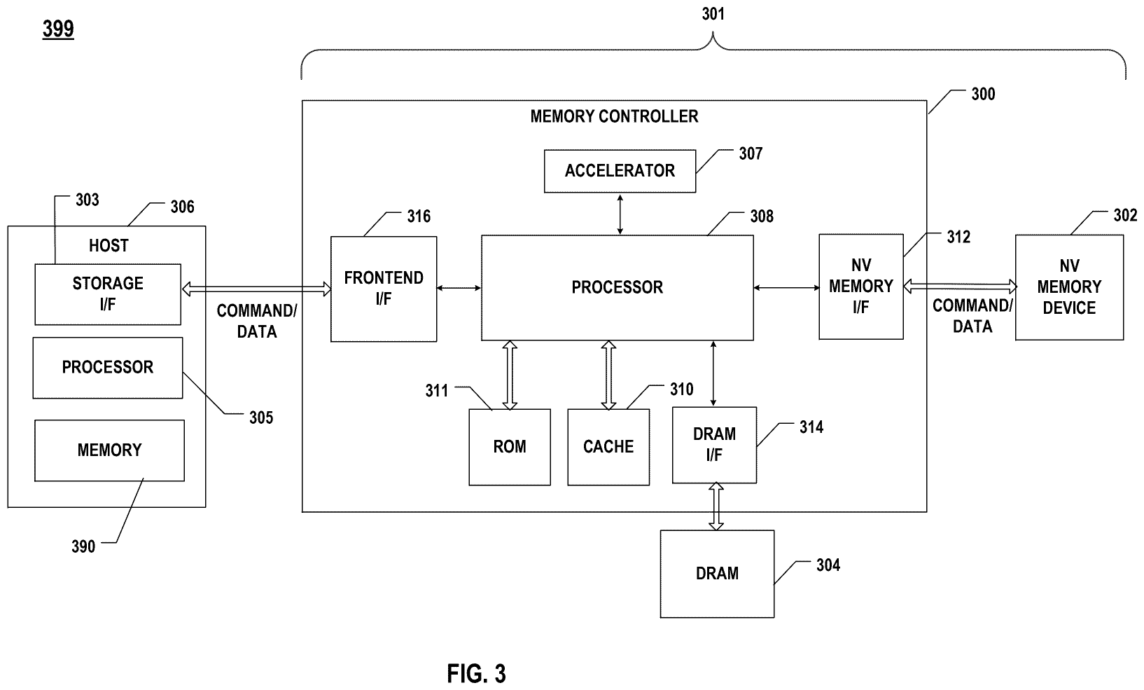

FIG. 3 illustrates another block diagram of a system 399 having a memory device, according to some aspects of the present disclosure. System 399 may be an example of system 100 in FIG. 1. System 399 may include a host 306 (e.g., an example of host 108 in FIG. 1) and a memory system 301 (e.g., an example of memory system 102 in FIG. 1). Memory system 301 may include a memory controller 300 (e.g., an example of memory controller 106 in FIG. 1) and a non-volatile memory device 302 (e.g., an example of memory device 104 in FIG. 1).

As shown in FIG. 3, memory controller 300 can include a processor 308, an accelerator 307 (e.g., a hardware accelerator), a cache 310, and a read-only memory (ROM) 311. In some implementations, processor 308 is implemented by microprocessors (e.g., digital signal processors (DSPs)) or microcontrollers (a.k.a. microcontroller units (MCUs)) that execute firmware and/or software modules to perform the various functions described herein. The various firmware modules in memory controller 300 described herein can be implemented as firmware codes or instructions stored in ROM 311 and executed by processor 308. In some implementations, processor 308 includes one or more hardware circuits, for example, fixed logic units such as a logic gate, a multiplexer, a flip-flop, a state machine, field-programmable gate arrays (FPGAs), programmable logic devices (PLDs). For example, the hardware circuits may include dedicated circuits performing a given logic function that is known at the time of device manufacture, such as application-specific integrated circuits (ASICs).

As shown in FIG. 3, memory controller 300 can also include various input/output (I/O) interfaces (I/F), such as a non-volatile memory interface 312, a DRAM interface 314, and a frontend interface 316 operatively coupled to non-volatile memory device 302 (e.g., flash memory), DRAM 304 (e.g., an example of volatile memory devices), and host 306, respectively. Non-volatile memory interface 312, DRAM interface 314, and frontend interface 316 can be configured to transfer data, command, clock, or any suitable signals between processor 308 and non-volatile memory device 302, DRAM 304, and host 306, respectively. Non-volatile memory interface 312, DRAM interface 314, and frontend interface 316 can implement any suitable communication protocols facilitating data transfer, communication, and management, such as the NVMe protocol and PCI-E protocol, double data rate (DDR) protocol, to name a few.

As described above, both cache 310 and DRAM 304 may be considered volatile memory devices that can be controlled and accessed by memory controller 300 in a memory system. In some implementations, a cache can be implemented as part of volatile memory devices, for example, by an SRAM and/or DRAM 304. It is understood that although FIG. 3 shows that cache 310 is within memory controller 300, and DRAM 304 is outside of memory controller 300. In some examples, both cache 310 and DRAM 304 may be within memory controller 300 or outside of memory controller 300.

In some implementations, DRAM 304 and DRAM I/F 314 may be optional components of memory system 301. That is, memory system 301 may not include DRAM 304 and DRAM I/F 314 in some examples. For example, memory system 301 may include a UFS device that does not have any DRAM therein.

Host 306 may include a storage interface (I/F) 303, a processor 305, and a memory 390. Storage interface 303 may be operatively coupled to frontend interface 316 of memory controller 300. Storage interface 303 may be configured to transfer data, command, or any suitable signals between host 306 and memory controller 300. Storage interface 303 can implement any suitable communication protocols facilitating data transfer, communication, and management, such as the NVMe protocol, the PCI-E protocol, SCSI, to name a few. Processor 305 may have a structure like that of processor 308, and a similar description will not be repeated herein.

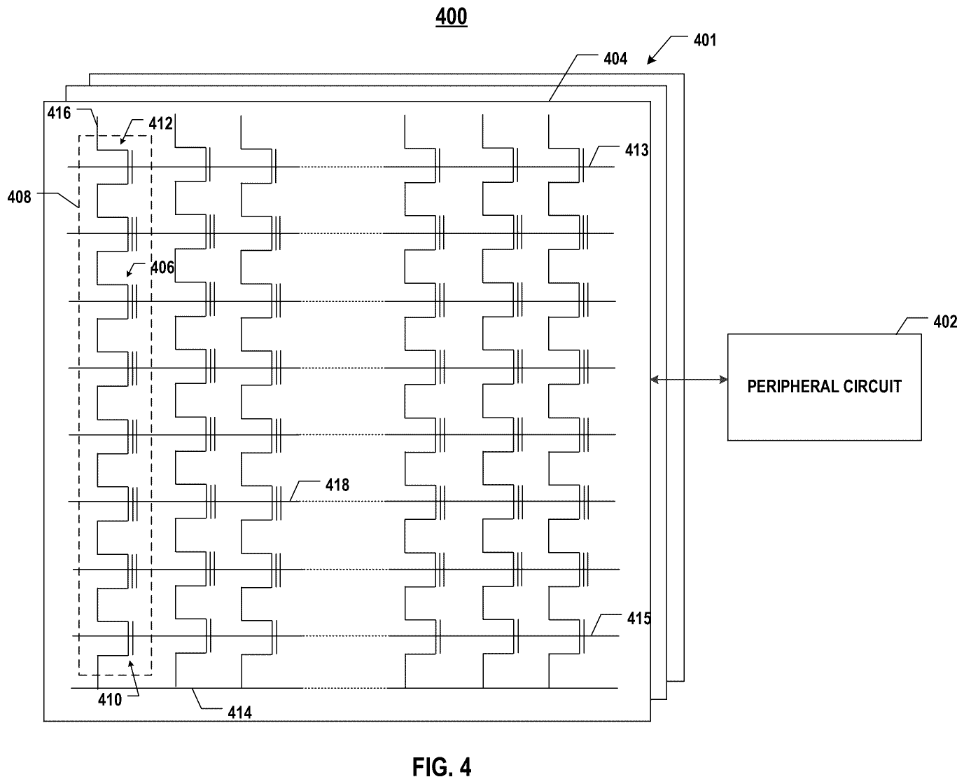

FIG. 4 illustrates a schematic diagram of a memory device 400 including peripheral circuits 402, according to some aspects of the present disclosure. Memory device 400 can be an example of memory device 104 in FIG. 1 or memory device 302 in FIG. 3. Memory device 400 can include a memory cell array 401 and peripheral circuits 402 coupled to memory cell array 401. Memory cell array 401 can be a NAND Flash memory cell array in which memory cells 406 are provided in an array of NAND memory strings 408 each extending vertically above a substrate (not shown). In some implementations, each NAND memory string 408 includes a plurality of memory cells 406 coupled in series and stacked vertically. Each memory cell 406 can hold a continuous, analog value, such as an electrical voltage or charge, that depends on the number of electrons trapped within a region of memory cell 406. Each memory cell 406 can be either a floating gate type of memory cell including a floating-gate transistor or a charge trap type of memory cell including a charge-trap transistor.

In some implementations, each memory cell 406 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 406 is a multi-level cell (MLC) that is capable of storing more than a single bit of data in more than four memory states. For example, the MLC can store two bits per cell, three bits per cell (also known as TLC), or four bits per cell (also known as QLC). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 4, each NAND memory string 408 can also include a source select gate (SSG) transistor 410 at its source end and a drain select gate (DSG) transistor 412 at its drain end. SSG transistor 410 and DSG transistor 412 can be configured to activate select NAND memory strings 408 (columns of the array) during read and program operations. In some implementations, the sources of NAND memory strings 408 in the same block 404 are coupled through a same source line (SL) 414, e.g., a common SL. In other words, all NAND memory strings 408 in the same block 404 have an array common source (ACS), according to some implementations. The drain of each NAND memory string 408 is coupled to a respective bit line 416 from which data can be read or written via an output bus (not shown), according to some implementations. In some implementations, each NAND memory string 408 is configured to be selected or deselected by applying a DSG select voltage or a DSG unselect voltage to the gate of respective DSG transistor 412 through one or more DSG lines 413 and/or by applying an SSG select voltage or an SSG unselect voltage to the gate of respective SSG transistor 410 through one or more SSG lines 415.

As shown in FIG. 4, NAND memory strings 408 can be organized into multiple blocks 404, each of which can have a common source line 414, e.g., coupled to an ACS. In some implementations, each block 404 is the basic data unit for erase operations, i.e., all memory cells 406 on the same block 404 are erased at the same time. To erase memory cells 406 in a select block 404, source lines 414 coupled to select block 404 as well as unselect blocks 404 in the same plane as select block 404 can be biased with an erase voltage (Vers), such as a high positive voltage (e.g., 20 V or more). Memory cells 406 of adjacent NAND memory strings 408 can be coupled through word lines 418 that select which row of memory cells 406 is affected by read and program operations. Each word line 418 can include a plurality of control gates (gate electrodes) at each memory cell 406 coupled to word line 418 and a gate line coupling the control gates. With reference to FIG. 4, a plurality of word lines WL(0), WL(1), WL(2), . . . , WL(n−1), WL(n), WL(n+1), and WL(n+2) are illustrated, with n being a positive integer.

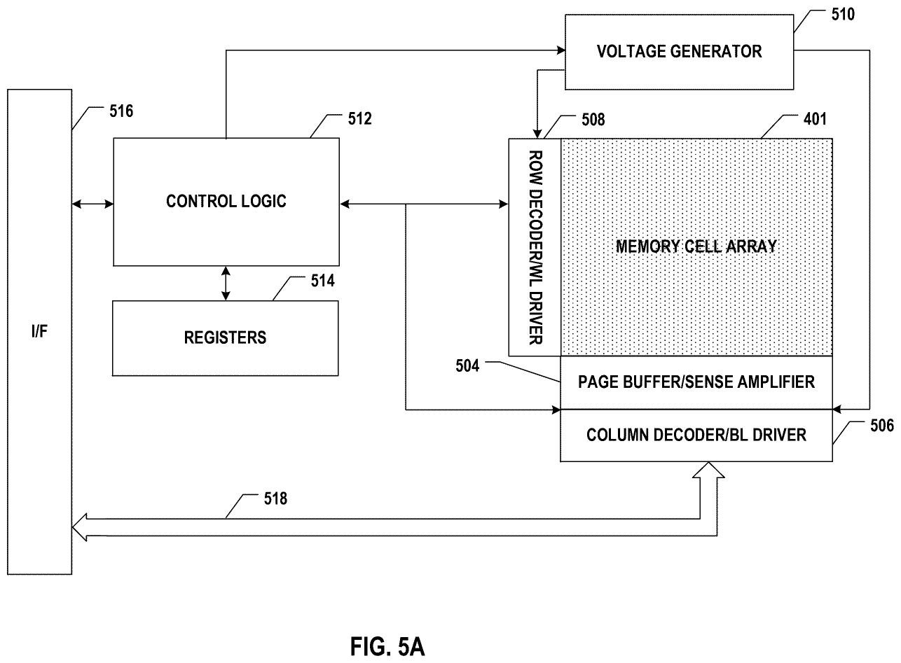

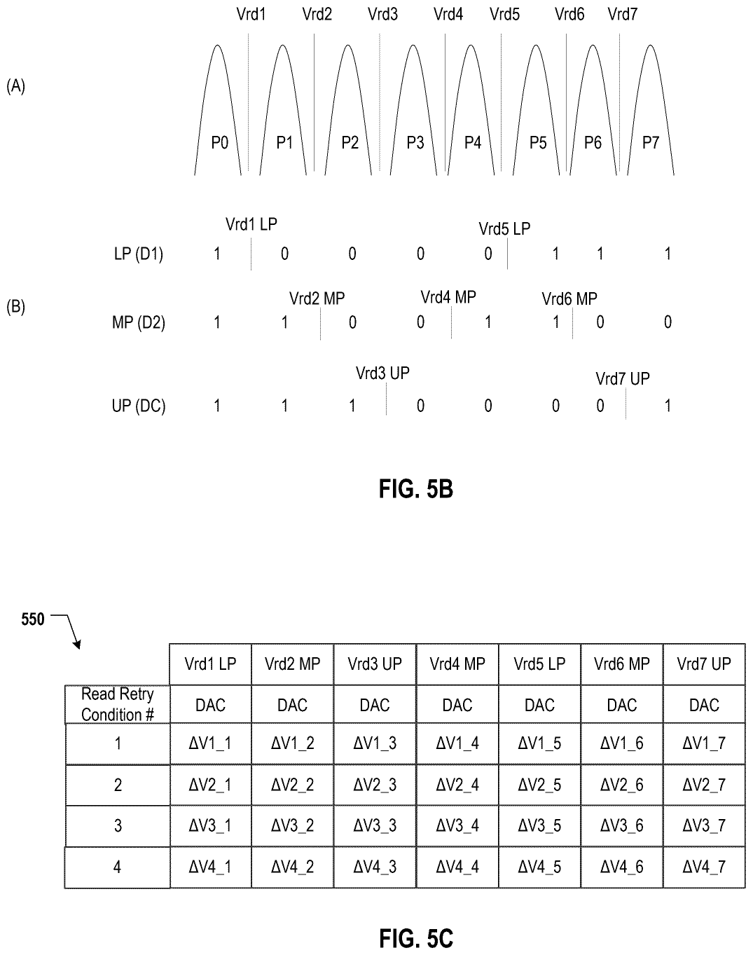

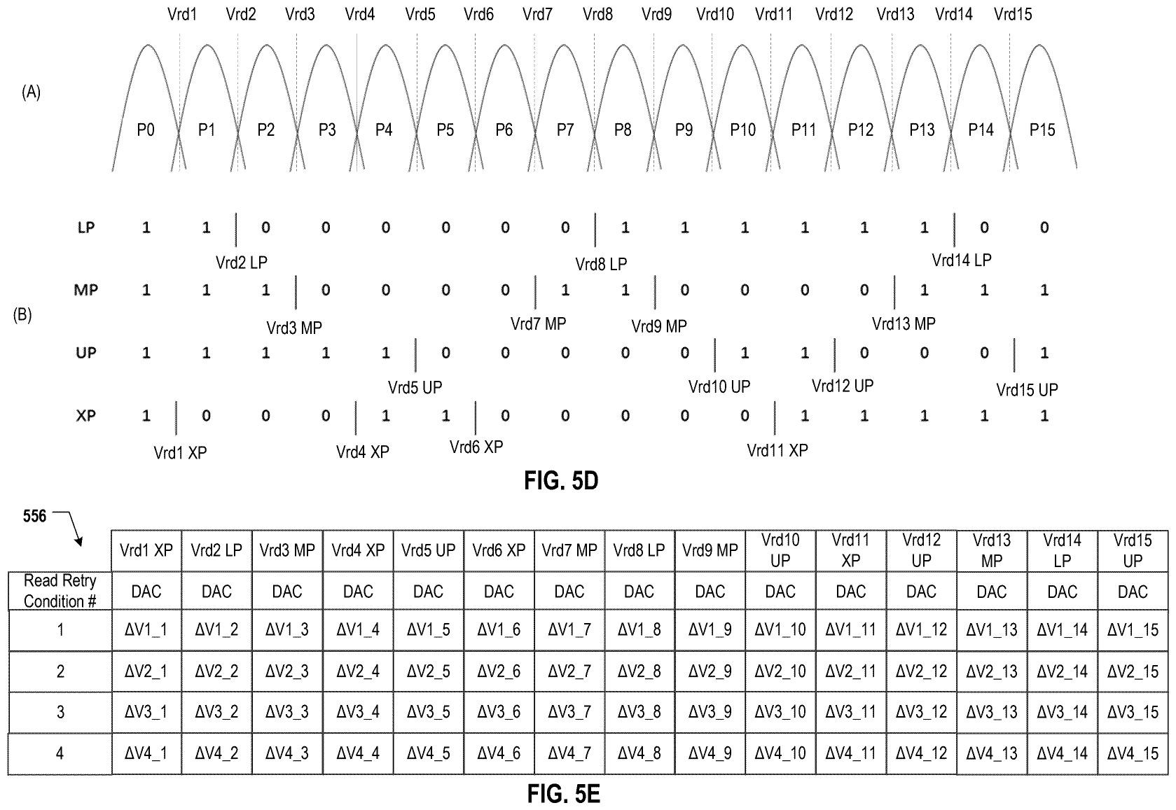

Peripheral circuits 402 can be coupled to memory cell array 401 through bit lines 416, word lines 418, source lines 414, SSG lines 415, and DSG lines 413. Peripheral circuits 402 can include any suitable analog, digital, and mixed-signal circuits for facilitating the operations of memory cell array 401 by applying and sensing voltage signals and/or current signals to and from each target memory cell 406 through bit lines 416, word lines 418, source lines 414, SSG lines 415, and DSG lines 413. Peripheral circuits 402 can include various types of peripheral circuits formed using metal-oxide-semiconductor (MOS) technologies. For example, FIG. 5A illustrates some peripheral circuits including a page buffer/sense amplifier 504, a column decoder/bit line driver 506, a row decoder/word line driver 508, a voltage generator 510, control logic 512, registers 514, an interface 516, and a data bus 518. It is understood that in some examples, additional peripheral circuits not shown in FIG. 5A may be included as well.

Page buffer/sense amplifier 504 can be configured to read and program (write) data from and to memory cell array 401 according to the control signals from control logic 512. In one example, page buffer/sense amplifier 504 may store program data (write data) to be programmed. In another example, page buffer/sense amplifier 504 may verify programmed target memory cells 406 in each program/verify loop (cycle) in a program operation to ensure that the data has been properly programmed into memory cells 406 coupled to select word lines 418. In still another example, page buffer/sense amplifier 504 may also sense the low power signals from bit line 416 that represents a data bit stored in memory cell 406 and amplify the small voltage swing to recognizable logic levels in a read operation. In program operations, page buffer/sense amplifier 504 can include storage modules (e.g., latches, caches, registers, etc.) for temporarily storing a set of N-bits data (e.g., in the form of gray codes) received from data bus 518 and providing the set of N-bits data to a corresponding target memory cell 406 through the corresponding bit line 416 in each program pass of a multi-pass program operation.

Column decoder/bit line driver 506 can be configured to be controlled by control logic 512 and select one or more NAND memory strings 408 by applying bit line voltages generated from voltage generator 510. Row decoder/word line driver 508 can be configured to be controlled by control logic 512 and select/deselect blocks 404 of memory cell array 401 and select/deselect word lines 418 of block 404. Row decoder/word line driver 508 can be further configured to drive word lines 418 using word line voltages generated from voltage generator 510. In some implementations, row decoder/word line driver 508 can also select/deselect and drive SSG lines 415 and DSG lines 413 as well. Voltage generator 510 can be configured to be controlled by control logic 512 and generate the word line voltages (e.g., read voltage, program voltage, channel pass voltage, local voltage, verify voltage, etc.), bit line voltages, and source line voltages to be supplied to memory cell array 401.

Control logic 512 can be coupled to each peripheral circuit described above and configured to control the operations of each peripheral circuit. Registers 514 can be coupled to control logic 512 and include status registers, command registers, and address registers for storing status information, command operation codes (OP codes), and command addresses for controlling the operations of each peripheral circuit. Interface 516 can be coupled to control logic 512 and act as a control buffer to buffer and relay control commands received from a host (e.g., 108 in FIG. 1) to control logic 512 and status information received from control logic 512 to the host. Interface 516 can also be coupled to column decoder/bit line driver 506 via data bus 518 and act as a data input/output (I/O) interface and a data buffer to buffer and relay the data to and from memory cell array 401.

FIG. 5B illustrates read voltages of a TLC memory cell, according to some aspects of the present disclosure. Section (A) of FIG. 5B illustrates threshold voltage (Vth) distributions of TLC memory cells. As shown in section (A) of FIG. 5B, a TLC memory cell may be programmed into one of 8 memory states, including the erased state (P0) and 7 program states (P1-P7). Each memory state may correspond to a respective Vth range of memory cells. For example, the memory state P0 may correspond to the lowest threshold voltage range (the left-most threshold voltage distribution in section (A) of FIG. 5B), the memory state P1 may correspond to the second-lowest threshold voltage range (the second left-most threshold voltage distribution in section (A) of FIG. 5B), and similarly, the memory state P7 may correspond to the highest threshold voltage range (the right-most threshold voltage distribution in section (A) of FIG. 5B).

Consistent with some aspects of the present disclosure, each memory cell can be configured to store a set of N-bits data in one of 2^{N} memory states, where N is an integer greater than 1 (e.g., N=2 for MLCs, N=3 for TLCs, N=4 for QLCs, etc.). Each memory state can correspond to one of 2^{N} Vth ranges of memory cells. Each set of N-bits data can be described by N pages, where each page corresponds to one bit of the N bits. A read operation performed on a memory cell storing a set of N-bits data can include a plurality of single level reads (SLRs) on the memory cell with a plurality of read voltages, respectively. The plurality of SLRs may include one or more SLRs for each page using one or more corresponding read voltages, respectively, so that a value of the page can be determined through the one or more SLRs. For example, the plurality of SLRs may include one or more first SLRs for a first page using one or more first read voltages, respectively, such that whether the first page of the memory cell is 0 or 1 can be determined based on one or more first reading results of the one or more first SLRs. The plurality of SLRs may also include one or more second SLRs for a second page using one or more second read voltages, respectively, such that whether the second page of the memory cell is 0 or 1 can be determined based on one or more second reading results of the one or more second SLRs. Similarly, the plurality of SLRs may also include one or more N^{th} SLRs for an N^{th} page using one or more N^{th} read voltages, respectively, such that whether the N^{th} page of the memory cell is 0 or 1 can be determined based on one or more N^{th} reading results of the one or more N^{th} SLRs.

In a first example as shown in FIG. 5B, for TLCs, each set of 3-bits data may be represented using an upper page (UP), a middle page (MP), and a lower page (LP). Section (B) of FIG. 5B illustrates a respective set of 3-bits data corresponding to each of the 8 memory states P0-P7 (or each of 8 Vth ranges). For example, memory state P0 may correspond to 111, where each of the LP, MP, and UP is 1. Memory State P1 may correspond to 110, where each of the UP and MP is 1, and the LP is 0. Similarly, memory state P2 may correspond to 100, where the UP is 1, and each of the MP and LP is 0.

During a read operation performed on a TLC memory cell, seven read voltages (Vrd1, Vrd2, Vrd3, Vrd4, Vrd5, Vrd6, Vrd7) can be applied to a word line coupled to the TLC memory cell to obtain seven reading results, respectively. As a result, the 3 bits of data stored in the TLC memory cell can be determined based on the reading results. For example, the read operation performed on the TLC memory cell can include seven SLRs on the memory cell with seven read voltages (Vrd1, Vrd2, Vrd3, Vrd4, Vrd5, Vrd6, Vrd7), respectively. During the read operation of the TLC memory cell, some or all of the seven SLRs can be performed by applying some or all of the seven read voltages (Vrd1, Vrd2, Vrd3, Vrd4, Vrd5, Vrd6, Vrd7) to a word line coupled to the TLC memory cell, respectively. As a result, the 3 bits of data stored in the TLC memory cell can be determined based on reading results of some or all of the seven SLRs.

Specifically, read voltages Vrd1 and Vrd5 can be applied to the word line coupled to the TLC memory cell to obtain a first reading result and a second reading result associated with the lower page, respectively. Then, the lower page of the memory cell can be determined based on the first and second reading results. For instance, the seven SLRs may include two lower-page reads for the lower page using two read voltages Vrd1 and Vrd5, respectively, where Vrd1 and Vrd5 are also labeled as “Vrd1 LP” and “Vrd5 LP” to indicate that they are read voltages related to reading the lower page. For example, by performing a first lower-page read on the memory cell using the read voltage Vrd1, the first reading result may be obtained. Next, by performing a second lower-page read on the memory cell using the read voltage Vrd5, the second reading result may be obtained. If the first reading result indicates that a Vth of the memory cell is greater than Vrd1 and the second reading result indicates that the Vth of the memory cell is smaller than Vrd5 (e.g., Vrd1<the Vth of the memory cell<Vrd5), the lower page of the memory cell is determined to be 0. Otherwise (e.g., the Vth of the memory device<Vrd1, or the Vth of the memory cell>Vrd5), the lower page of the memory cell is determined to be 1.

Next, read voltages Vrd2, Vrd4, and Vrd6 can be applied to the word line coupled to the TLC memory cell to obtain corresponding reading results associated with the middle page, respectively. Then, the middle page of the memory cell can be determined based on the corresponding reading results. For instance, the seven SLRs may also include three middle-page reads for the middle page using three read voltages Vrd2, Vrd4, and Vrd6, respectively, where Vrd2, Vrd4, and Vrd6 are also labeled as “Vrd2 MP,” “Vrd4 MP,” and “Vrd6 MP” to indicate that they are read voltages related to reading the middle page. For example, the three middle-page reads may be performed on the memory cell using three read voltages Vrd2, Vrd4, and Vrd6, respectively. If the reading results of the three middle-page reads indicate that the Vth of the memory cell is greater than Vrd2 but smaller than Vrd4 or greater than Vrd6 (e.g., Vrd2<the Vth of the memory cell<Vrd4, or the Vth of the memory cell>Vrd6), the middle page of the memory cell is determined to be 0. Otherwise (e.g., the Vth of the memory cell<Vrd2, or Vrd4<the Vth of the memory cell<Vrd6), the middle page of the memory cell is determined to be 1.

Further, read voltages Vrd3 and Vrd7 can be applied to the word line coupled to the TLC memory cell to obtain corresponding reading results associated with the upper page, respectively. Then, the upper page of the memory cell can be determined based on the corresponding reading results. For instance, the seven SLRs may further include two upper-page reads for the upper page using two read voltages Vrd3 and Vrd7, respectively, where Vrd3 and Vrd7 are also labeled as “Vrd3 UP” and “Vrd7 UP” to indicate that they are read voltages related to reading the upper page. For example, the two upper-page reads may be performed on the memory cell using two read voltages Vrd3 and Vrd7, respectively. If the reading results of the two upper-page reads indicate that the Vth of the memory cell is greater than Vrd3 but smaller than Vrd7 (e.g., Vrd3<the Vth of the memory cell<Vrd7), the upper page of the memory cell is determined to be 0. Otherwise (e.g., the Vth of the memory cell<Vrd3, or the Vth of the memory cell>Vrd7), the upper page of the memory cell is determined to be 1.

In a second example as shown in FIG. 5D, read voltages of a QLC memory cell are illustrated. Section (A) of FIG. 5D illustrates Vth distributions of QLC memory cells. For QLCs, each set of 4-bits data may be represented using an extra page (XP), a UP, an MP, and an LP. Section (B) of FIG. 5D illustrates a respective set of 4-bits data corresponding to each of 16 memory states P0-P15 (or each of 16 Vth ranges). For example, memory state P0 may correspond to 1111, where each of the LP, MP, UP, and XP is 1. Memory state P1 may correspond to 0111, where each of the UP, MP, and LP is 1, and the XP is 0.

During a read operation performed on a QLC memory cell, fifteen read voltages (Vrd1, Vrd2, Vrd3, Vrd4, Vrd5, Vrd6, Vrd7, Vrd8, Vrd9, Vrd10, Vrd11, Vrd12, Vrd13, Vrd14, Vrd15) can be applied to a word line coupled to the QLC memory cell to obtain fifteen reading results, respectively. As a result, 4 bits of data stored in the QLC memory cell can be determined based on the reading results. For example, the read operation performed on the QLC memory cell can include fifteen SLRs on the memory cell with fifteen read voltages (Vrd1-Vrd15), respectively. During the read operation of the QLC memory cell, some or all of the fifteen SLRs can be performed by applying some or all of the fifteen read voltages Vrd1-Vrd15 to the word line coupled to the QLC memory cell, respectively. As a result, 4 bits of data stored in the QLC memory cell can be determined based on reading results of some or all of the fifteen SLRs.

Specifically, read voltages Vrd2, Vrd8, and Vrd14 can be applied to the word line coupled to the QLC memory cell to obtain corresponding reading results associated with the lower page, respectively. Then, the lower page of the memory cell can be determined based on the corresponding reading results. For example, the fifteen SLRs may include three lower-page reads for the lower page using three read voltages Vrd2, Vrd8, and Vrd14, respectively, where Vrd2, Vrd8, and Vrd14 are also labeled as “Vrd2 LP,” “Vrd8 LP” and “Vrd14 LP” to indicate that they are read voltages related to reading the lower page. A value of the lower page of the memory cell can be determined based on reading results of the lower-page reads.

Next, read voltages Vrd3, Vrd7, Vrd9, and Vrd13 can be applied to the word line coupled to the QLC memory cell to obtain corresponding reading results associated with the middle page, respectively. Then, the middle page of the memory cell can be determined based on the corresponding reading results. For example, the fifteen SLRs may also include four middle-page reads for the middle page using four read voltages Vrd3, Vrd7, Vrd9, and Vrd13, respectively, where Vrd3, Vrd7, Vrd9, and Vrd13 are also labeled as “Vrd3 MP,” “Vrd7 MP,” “Vrd9 MP,” and “Vrd13 MP” to indicate that they are read voltages related to reading the middle page. The value of the middle page of the memory cell can be determined based on reading results of the middle-page reads.

Further, read voltages Vrd5, Vrd10, Vrd12, and Vrd15 can be applied to the word line coupled to the QLC memory cell to obtain corresponding reading results associated with the upper page, respectively. Then, the upper page of the memory cell can be determined based on the corresponding reading results. For example, the fifteen SLRs may further include four upper-page reads for the upper page using four read voltages Vrd5, Vrd10, Vrd12, and Vrd15, respectively, where Vrd5, Vrd10, Vrd12, and Vrd15 are also labeled as “Vrd5 UP,” “Vrd10, UP,” “Vrd12 UP,” and “Vrd15 UP” to indicate that they are read voltages related to reading the upper page. A value of the upper page of the memory cell can be determined based on reading results of the upper-page reads.

Subsequently, read voltages Vrd1, Vrd4, Vrd6, and Vrd11 can be applied to the word line coupled to the QLC memory cell to obtain corresponding reading results associated with the extra page, respectively. Then, the extra page of the memory cell can be determined based on the corresponding reading results. For example, the fifteen SLRs may include four extra-page reads for the extra page using four read voltages Vrd1, Vrd4, Vrd6, and Vrd11, respectively, where Vrd1, Vrd4, Vrd6, and Vrd11 are also labeled as “Vrd1 XP,” “Vrd4 XP,” “Vrd6 XP,” and “Vrd11 XP” to indicate that they are read voltages related to reading the extra page. A value of the extra page of the memory cell can be determined based on the reading results of the extra-page reads.

FIG. 5C illustrates an example read retry table for a TLC memory cell, according to some aspects of the present disclosure. Read retry and adjustments of read voltages may be a way to correct errors caused by the data retention problem. Read retry may allow a user to change the read voltages that separate the different memory states of memory cells. For example, a read retry operation may include a plurality of retry reads that test different read voltages to identify appropriate read voltages in view of charge distribution changes. In some implementations, a read retry table may include a number of read retry conditions with adjusted read voltages. The adjusted read voltages obtained from the read retry table can be used to avoid errors caused by the shifting of charge levels. Each read retry condition in the read retry table may include a plurality of adjusted read voltages for a corresponding retry read.

In some implementations, a read retry table may include a number of read retry conditions with read voltage offsets used to adjust the read voltages. The adjusted read voltages calculated based on the read voltages offsets from the read retry table can be used to avoid errors caused by shifting of charge levels. Each read retry condition in the read retry table may include a plurality of read voltage offsets used to adjust a plurality of read voltages for the corresponding retry read.

For example, referring to FIG. 5C, a read retry table 550 may include four read retry conditions for performing a read retry operation on a TLC memory cell. Each read retry condition may include a plurality of read voltage offsets used to adjust the read voltages Vrd1-Vrd7 of FIG. 5B, respectively. For example, a first read retry condition #1 may include read voltage offsets ΔV1_1, ΔV1_2, . . . , and ΔV1_7 for the read voltages Vrd1-Vrd7, respectively. If the first read retry condition #1 is selected in the read retry operation, the read voltages Vrd1-Vrd7 can be adjusted using the read voltage offsets ΔV1_1, ΔV1_2, . . . , and ΔV1_7, respectively (e.g., the adjusted read voltage Vrd1=a default value of the read voltage Vrd1+the read voltage offset ΔV1_1, the adjusted read voltage Vrd2=a default value of the read voltage Vrd2+the read voltage offset ΔV1_2, etc.). Then, a retry read is performed to read the memory cell using the adjusted read voltages Vrd1-Vrd7.

FIG. 5E illustrates an example read retry table 556 for a QLC memory cell, according to some aspects of the present disclosure. Read retry table 556 may include four read retry conditions for performing a read retry operation on a QLC memory cell. Each read retry condition may include a plurality of read voltage offsets used to adjust the read voltages Vrd1-Vrd15 of FIG. 5D, respectively. For example, a first read retry condition #1 may include read voltage offsets ΔV1_1, ΔV1_2, . . . , and ΔV1_15 for the read voltages Vrd1-Vrd15, respectively. If the first read retry condition #1 is selected in the read retry operation, the read voltages Vrd1-Vrd15 can be adjusted using the read voltage offsets ΔV1_1, ΔV1_2, . . . , and ΔV1_15, respectively (e.g., the adjusted read voltage Vrd1=a default value of the read voltage Vrd1+the read voltage offset ΔV1_1, the adjusted read voltage Vrd2=a default value of the read voltage Vrd2+the read voltage offset ΔV1_2, etc.). Then, a retry read is performed to read the memory cell using the adjusted read voltages Vrd1-Vrd15.

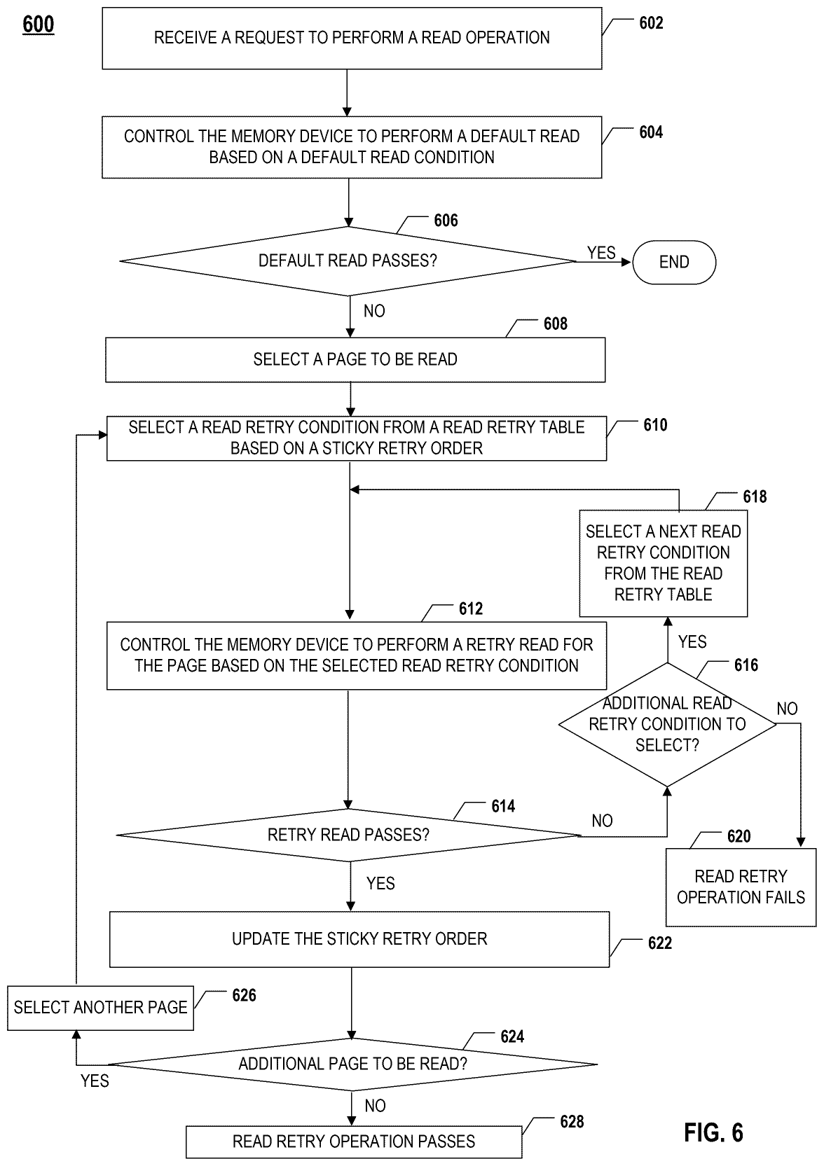

FIG. 6 illustrates a flowchart of a method 600 for operating a memory controller, according to some examples of the present disclosure. Method 600 may be performed by a memory controller, which can be any memory controller disclosed herein, such as memory controller 106 of FIG. 1 or memory controller 300 of FIG. 3. The memory controller can be communicatively coupled to a memory device, such as memory device 104 of FIG. 1 or memory device 302 of FIG. 3. It is understood that the operations shown in method 600 may not be exhaustive and that other operations can be performed as well before, after, or between any of the illustrated operations. Further, some of the operations may be performed simultaneously, or in a different order than shown in FIG. 6.

Method 600 may begin with operation 602 in which the memory controller (e.g., a processor of the memory controller) may receive a request for performing a read operation to read a memory cell of the memory device coupled to the memory controller. The memory cell may include a plurality of pages. For example, if the memory cell is a TLC, the plurality of pages may include a lower page, a middle page, and an upper page.

Method 600 may proceed to operation 604, in which the memory controller may control or instruct the memory device to perform a default read on the memory cell based on a default read condition. For example, the default read condition may include a plurality of default read voltages for reading the memory cell.

Method 600 may proceed to operation 606, in which the memory controller may determine whether the default read passes. If the default read passes (e.g., the default read reads out the memory cell successfully), method 600 ends. Otherwise (e.g., the default read fails to read out the memory cell), method 600 proceeds to operation 608.

Operations 608-628 described below may include performing a read retry operation on the memory cell. The read retry operation may include one or more retry reads using one or more read retry conditions from a read retry table for each page, as shown in operations 612-618 below.

At operation 608, the memory controller may select a page from the plurality of pages to be read. For example, the memory controller may select a lower page to be read.

Method 600 may proceed to operation 610, in which the memory controller may select a read retry condition from a read retry table based on a sticky retry order. Each read retry condition in the read retry table may include, for example, a plurality of read voltage offsets for a plurality of read voltages, respectively. The stick retry order may indicate an identifier of a read retry condition capable of reading out at least one of the plurality of pages in a previous read, and this read retry condition can be referred to as a sticky read retry condition. For example, the sticky retry order can be denoted as p, indicating that the sticky read retry condition is the read retry condition p. A maximum retry order can be denoted as M−1, indicating that there are M−1 read retry conditions (0, 1, 2, . . . , p, . . . , M−1) available in the read retry table. At operation 610, the read retry condition corresponding to the sticky retry order (e.g., the sticky read retry condition) is selected.

Method 600 may proceed to operation 612, in which the memory controller may control the memory device to perform a retry read for the page based on the selected read retry condition. Specifically, the memory controller may update one or more read voltages for the page based on one or more read voltage offsets related to the page from the selected read retry condition. The memory controller may apply the one or more updated read voltages to read the page of the memory cell. For example, assuming that the memory cell is a TLC and the selected read retry condition is the read retry condition #3 in read retry table 550 of FIG. 5C. The selected page is the lower page. Then, the memory controller may update the read voltages Vrd1 and Vrd5 for the lower page based on corresponding read voltage offsets ΔV3_1 and ΔV3_5 from the read retry condition #3, respectively. The memory controller may apply the updated read voltages Vrd1 and Vrd5 to read the lower page of the memory cell.

Method 600 may proceed to operation 614, in which the memory controller may determine whether the retry read (which reads the selected page of the memory cell) passes. If the retry read passes, method 600 may proceed to operation 622. Otherwise, method 600 may proceed to operation 616. In some implementations, an execution of operations 610, 612, and 614 may constitute a retry read using the selected read retry condition for the selected page.

At operation 616 (when the retry read at operation 614 fails), the memory controller may determine whether there is at least an additional read retry condition to be selected from the read retry table. If there is at least an additional read retry condition to be selected, method 600 may proceed to operation 618. Otherwise (e.g., there is no additional read retry condition to be selected, or equivalently, all the read retry conditions in the read retry table are already selected and fail in the retry read), method 600 may proceed to operation 620, which indicates that the read retry operation fails.

At operation 618, the memory controller may select the next read retry condition from the read retry table. For example, a read retry condition mod (p+1, M) can be selected next, and method 600 returns to operations 612 and 614. If the read retry condition mod (p+1, M) also fails in the retry read, then a read retry condition mod (p−1, M) can be selected subsequently. Further, if the read retry condition mod (p−1, M) also fails in the retry read, then a read retry condition mod (p+2, M) can be selected. Then, if the read retry condition mod (p+2, M) also fails in the retry read, then a read retry condition mod (p−2, M) can be selected. In this way, the read retry conditions in the read retry table can be traversed and selected for reading the page until the page is read out successfully or all the read retry conditions in the read retry table are traversed (e.g., the read retry operation fails). That is, in operations 610 and 618, the read retry condition is selected from the read retry table in the following order: the read retry condition p→the read retry condition mod (p+1, M)→the read retry condition mod (p−1, M)→the read retry condition mod (p+2, M)→the read retry condition mod (p−2, M), so on and so forth, until the page is read out successfully or all the read retry conditions in the read retry table are traversed.

At operation 622, the memory controller may update the sticky retry order to be an identifier of a read retry condition that reads out the page successfully. For example, if the read retry condition mod (p+1, M) succeeds in the retry read at operations 612 and 614, the sticky retry order is updated to be mod (p+1, M). In another example, if the read retry condition mod (p−2, M) succeeds in the retry read at operations 612 and 614, the sticky retry order is updated to mod (p−2, M).

Method 600 may proceed to operation 624, in which the memory controller may determine whether there is an additional page to be read. Responsive to determining that there is at least an additional page to be read, method 600 may proceed to operation 626. Otherwise (e.g., the plurality of pages are already read successfully), method 600 may proceed to operation 628.

At operation 626, the memory controller may select another page to be read. For example, if the lower page is already read, the memory controller may select a middle page to be read. Then, method 600 may return to operation 610 to select a read retry condition based on the updated sticky retry order to read the newly selected page. In some implementations, operations 610-618 and 622-626 may be performed repeatedly until each page from the plurality of pages is read.

At operation 628, the memory controller may determine that the read retry operation passes. In this case, the plurality of pages are read out successfully for the memory cell, and the read retry operation may be referred to as a passed read retry operation.

In method 600, the sticky retry order is updated only based on the latest passed retry read, and other historical passed retry reads are not considered in the update of the sticky retry order. Besides, only one sticky retry order is recorded for all the pages (e.g., the sticky retry order is not distinguished among the different pages). However, different pages may be read out successfully by using different read retry conditions, which are associated with different sticky retry orders. Using the same sticky retry order for all the pages may result in an increase in the read retry count. For example, a large number of retry reads may be needed to read out all the pages successfully. Then, the read latency may be large, leading to a performance downgrade in the memory system.

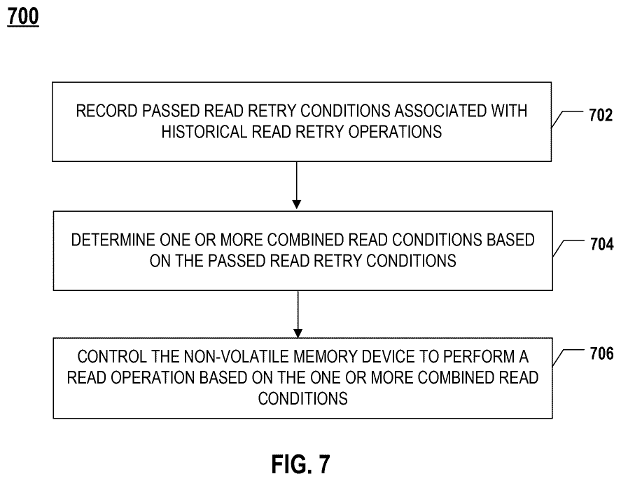

Consistent with some aspects of the present disclosure, an improved read scheme that can optimize the use of a read retry table is provided below with reference to FIGS. 7-10E. In the improved read scheme disclosed herein, one or more combined read conditions can be generated, and each of the combined read conditions can be applied to read all the pages. Further, the combined read conditions are generated based on various passed read retry conditions and the page types, such that the likelihood that the combined read conditions can be used to read out all the pages successfully can be improved. As a result, the read retry count can be reduced, the read latency can be reduced, and the performance of the memory system can be improved.

FIG. 7 illustrates a flowchart of a method 700 for operating a memory controller, according to some aspects of the present disclosure. Method 700 may be performed by a memory controller, which can be any memory controller disclosed herein, such as memory controller 106 of FIG. 1 or memory controller 300 of FIG. 3. The memory controller can be communicatively coupled to a memory device, such as memory device 104 of FIG. 1 or memory device 302 of FIG. 3. It is understood that the operations shown in method 700 may not be exhaustive and that other operations can be performed as well before, after, or between any of the illustrated operations. Further, some of the operations may be performed simultaneously, or in a different order than shown in FIG. 7.

The memory device may include memory cells, and each of the memory cells is configured to store at least two bits. The at least two bits are respectively corresponding to at least two pages. The at least two pages may include at least a first page and a second page. For example, the memory cells are TLCs, each of which stores 3 bits. The 3 bits correspond to a lower page, a middle page, and an upper page, respectively. In another example, the memory cells are QLCs, each of which stores 4 bits. The 4 bits correspond to a lower page, a middle page, an upper page, and an extra page, respectively.

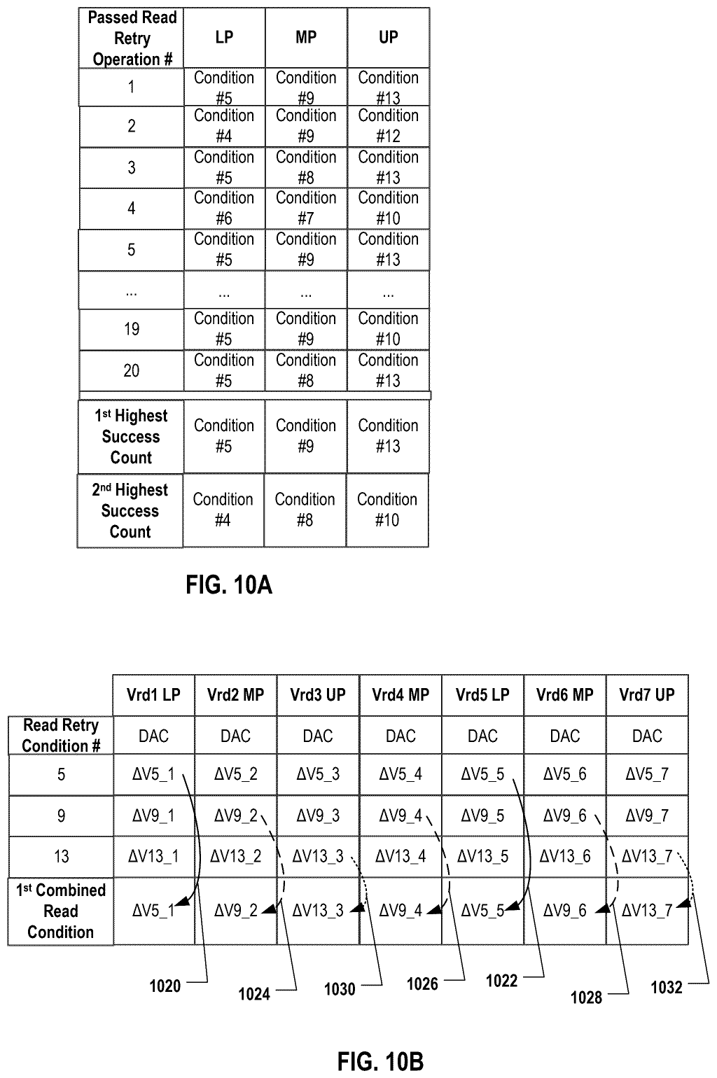

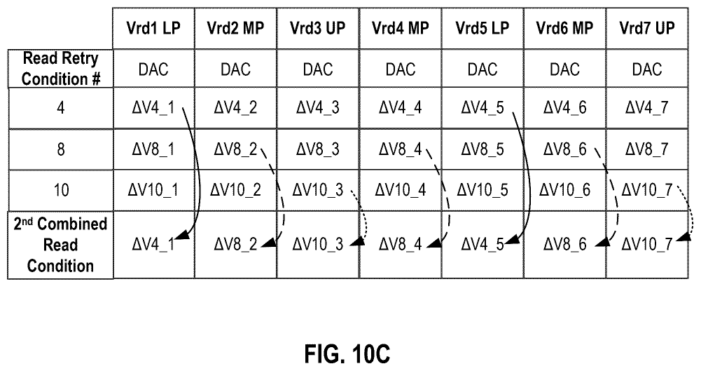

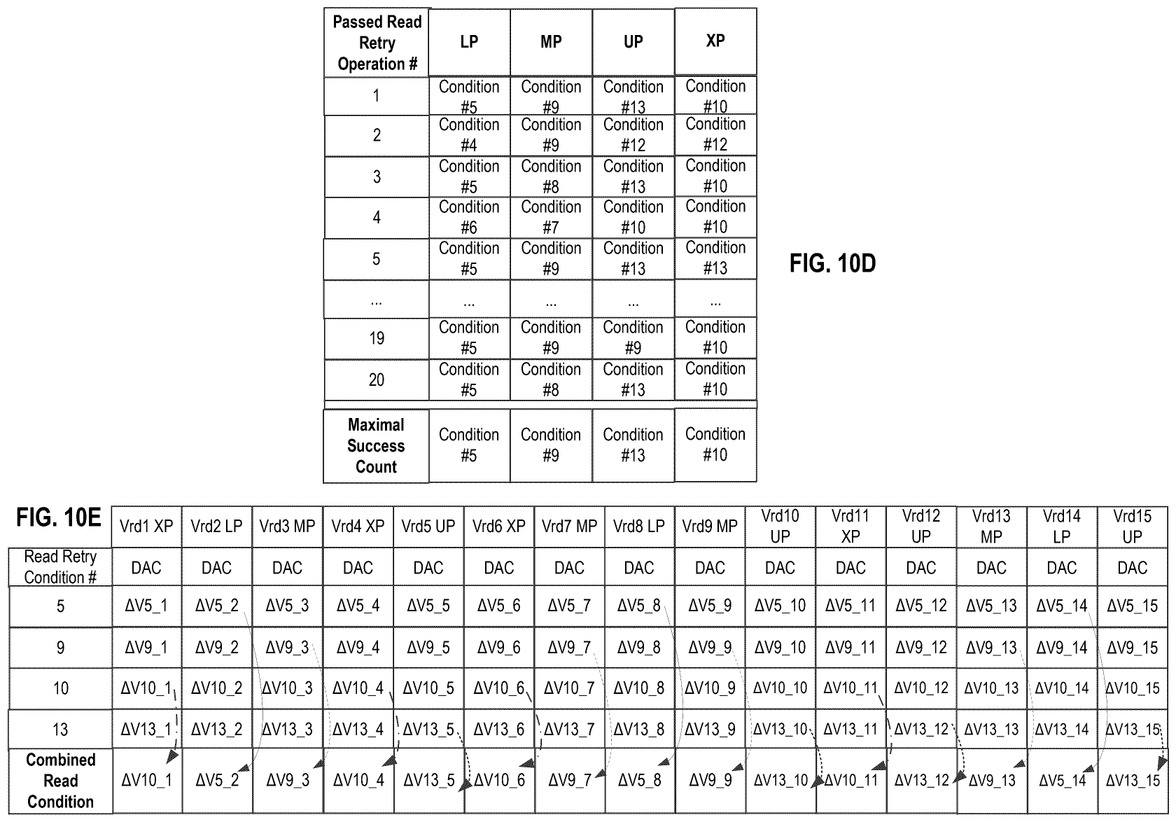

Method 700 may begin with operation 702 in which the memory controller (e.g., a processor of the memory controller) may record passed read retry conditions associated with historical read retry operations. The historical read retry operations may include a plurality of passed read retry operations performed on the memory device. Each passed read retry operation may be a read retry operation performed in the past, which can read out the pages of a memory cell successfully using one or more read retry conditions. The one or more read retry conditions associated with the passed read retry operation may be referred to as passed read retry conditions. The passed read retry conditions may be recorded based on the page types (e.g., as shown below in FIGS. 10A and 10D).

Consistent with some implementations of the present disclosure, for each historical passed read retry operation, the memory controller may record one or more passed read retry conditions for the historical passed read retry operation. Each passed read retry condition may include a read retry condition from a read retry table and be used to read out at least one page successfully in the historical passed read retry operation.

In some implementations, the one or more passed read retry conditions for the historical passed read retry operation may include a first passed read retry condition for the first page, which may include one or more first read parameters used to read out the first page successfully in the historical passed read retry operation. The one or more passed read retry condition may further include a second passed read retry condition for the second page, which may include one or more second read parameters used to read out the second page successfully in the historical passed read retry operation. Each of the one or more first read parameters and the one or more second read parameters may include a read voltage or a read voltage offset, which is not limited herein.

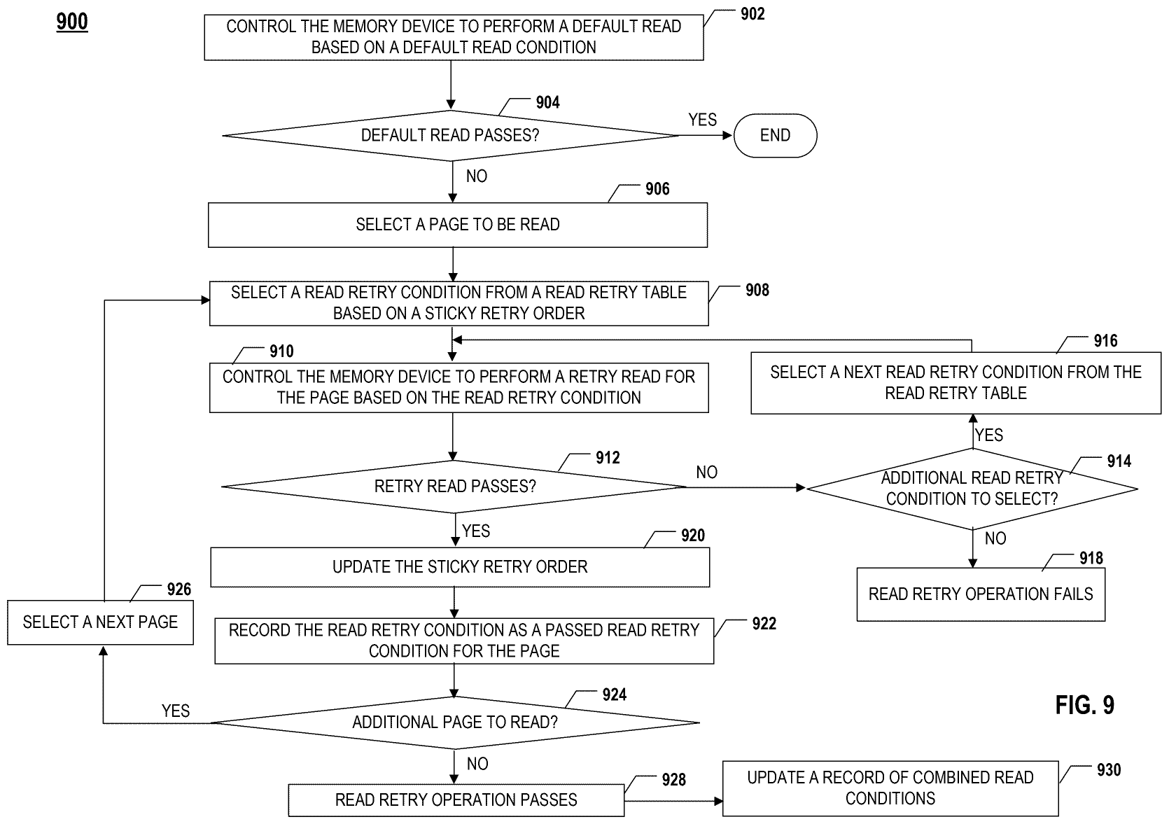

For example, with reference to FIGS. 5B-5C and FIG. 6 described above or FIG. 9 described below, assuming that a read retry operation is performed on a TLC memory cell. The read retry operation reads out the lower page of the TLC memory cell successfully using the read retry condition #1 in read retry table 550. That is, the lower page of the TLC memory cell is read out successfully by adjusting the read voltages Vrd1 LP and Vrd5 LP using the read voltage offsets ΔV1_1 and ΔV1_5 associated with the lower page from the read retry condition #1, respectively. The read retry operation reads out the middle page and the upper page of the TLC memory cell successfully using the read retry condition #3 in read retry table 550. That is, the middle page of the TLC memory cell is read out successfully by adjusting the read voltages Vrd2 MP, Vrd4 MP, and Vrd6 MP using the read voltage offsets ΔV3_2, ΔV3_4, and ΔV3_6 associated with the middle page from the read retry condition #3, respectively. The upper page of the TLC memory cell is read out successfully by adjusting the read voltages Vrd3 UP and Vrd7 UP using the read voltage offsets ΔV3_3 and ΔV3_7 associated with the upper page from the read retry condition #3, respectively. In this case, the read retry operation is recorded as a passed read retry operation associated with two passed read retry conditions (e.g., the read retry condition #1 for the lower page, and the read retry condition #3 for the middle page and the upper page). An example record of passed read retry operations and their respective passed read retry conditions for a TLC memory device is illustrated below in FIG. 10A.

In some implementations, the one or more passed read retry conditions for the historical passed read retry operation may include a passed read retry condition for all the pages. The passed read retry condition may include read parameters used to read out all the pages successfully in the historical passed read retry operation. Each of the read parameters may include a read voltage or a read voltage offset, which is not limited herein.

For example, with reference to FIGS. 5D-5E and FIG. 6 described above or FIG. 9 described below, assuming that a read retry operation is performed on a QLC memory cell and reads out the lower page, the middle page, the upper page, and the extra page of the QLC memory cell successfully using the read retry condition #4 in read retry table 556. That is, the lower page of the QLC memory cell is read out successfully by adjusting the read voltages Vrd2 LP, Vrd8 LP, and Vrd14 LP using the read voltage offsets ΔV4_2, ΔV4_8, and ΔV4_14 associated with the lower page from the read retry condition #4, respectively. The middle page of the QLC memory cell is read out successfully by adjusting the read voltages Vrd3 MP, Vrd7 MP, Vrd9 MP, and Vrd13 MP using the read voltage offsets ΔV4_3, ΔV4_7, ΔV4_9, and ΔV4_13 associated with the middle page from the read retry condition #4, respectively. The upper page of the QLC memory cell is read out successfully by adjusting the read voltages Vrd5 UP, Vrd10 UP, Vrd12 UP, and Vrd15 UP using the read voltage offsets ΔV4_5, ΔV4_10, ΔV4_12, and ΔV4_15 associated with the upper page from the read retry condition #4, respectively. The extra page of the QLC memory cell is read out successfully by adjusting the read voltages Vrd1 XP, Vrd4 XP, Vrd6 XP, and Vrd11 XP using the read voltage offsets ΔV4_1, ΔV4_4, ΔV4_6, and ΔV4_11 associated with the extra page from the read retry condition #4, respectively. In this case, the read retry operation is recorded as a passed read retry operation associated with one passed read retry condition (e.g., the read retry condition #4 for the lower page, the middle page, the upper page, and the extra page). An example record of passed read retry operations and their respective passed retry conditions for a QLC memory device is illustrated below in FIG. 10D.

Method 700 may proceed to operation 704, in which the memory controller may determine one or more combined read conditions based on the passed read retry conditions associated with the passed read retry operations. The memory controller may store the one or more combined read conditions in the memory device responsive to power off. The one or more combined read conditions may also be updated when the passed read retry operations and their respective passed read retry conditions are updated.

In some implementations, each combined read condition may include read parameters from at least two different passed read retry conditions. For example, the at least two pages may include a first page and a second page. Each combined read condition may include: (1) one or more first read parameters from a first one of the passed read retry conditions for the first page; and (2) one or more second read parameters from a second one of the passed read retry conditions for the second page.

In some implementations, the one or more combined read conditions may include a first combined read condition. The memory controller may determine optimal read retry conditions for the at least two pages, respectively, and combine the optimal read retry conditions to generate the first combined read condition based on the at least two pages.

Specifically, for each page from the at least two pages, the memory controller may determine an optimal read retry condition from the passed read retry conditions. The optimal read retry condition may include a passed read retry condition having a first highest success count to read out the corresponding page in the historical passed read retry operations. For example, the at least two pages may include a first page and a second page. The memory controller may determine, from the passed read retry conditions, (1) a first optimal read retry condition for the first page, which has a first highest success count to read out the first page in the historical passed read retry operations, and (2) a second optimal read retry condition for the second page which has a first highest success count to read out the second page in the historical passed read retry operations. The memory controller may generate the first combined read condition to include (1) one or more first read parameters from the first optimal read retry condition for the first page and (2) one or more second read parameters from the second optimal read retry condition for the second page.

In some implementations, the one or more combined read conditions may further include a second combined read condition. The memory controller may determine sub-optimal read retry conditions for the at least two pages, respectively, and combine the sub-optimal read retry conditions to generate the second combined read condition based on the at least two pages.

Specifically, for each page from the at least two pages, the memory controller may determine a sub-optimal read retry condition from the passed read retry conditions. The sub-optimal read retry condition may include a passed read retry condition having a second highest success count to read out the corresponding page in the historical passed read retry operations. For example, the at least two pages may include a first page and a second page. The memory controller may determine, from the passed read retry conditions, (1) a first sub-optimal read retry condition for the first page which has a second highest success count to read out the first page in the historical passed read retry operations, and (2) a second sub-optimal read retry condition for the second page which has a second highest success count to read out the second page in the historical passed read retry operations. The memory controller may generate the first combined read condition to include (1) one or more first read parameters from the first sub-optimal read retry condition for the first page and (2) one or more second read parameters from the second sub-optimal read retry condition for the second page.

In some implementations, the one or more combined read conditions may further include at least an additional combined read conditions (e.g., a third combined read condition, a fourth combined read condition, etc.). For each additional combined read condition, the memory controller may determine a corresponding additional sub-optimal read retry condition for each page, and combine the corresponding sub-optimal read retry conditions for all the pages to generate the additional combined read condition, by performing operations like those described above. The additional sub-optimal read retry condition for a corresponding page may include a passed read retry condition having a third highest success count, a fourth highest success count, etc., to read out the corresponding page in the historical passed read retry operations. It is contemplated that the number of the combined read conditions generated herein can be 1, 2, 3, or any other suitable integer, which is not limited herein.

An example generation of combined read conditions for a TLC memory device is illustrated in FIGS. 10A-10C. Referring to FIG. 10A, 20 latest passed read retry operations (#1-#20) and their respective passed read retry conditions are recorded. For example, a first passed read retry operation #1 is recorded, which is associated with a first passed read retry condition for the lower page (e.g., read retry condition #5 in a read retry table), a second passed read retry condition for the middle page (e.g., read retry condition #9 in the read retry table), and a third passed read retry condition for the upper page (e.g., read retry condition #13 in the read retry table).

Based on the record of the 20 passed read retry operations, a passed read retry condition having the first highest success count for the lower page (e.g., a first optimal read retry condition for the lower page) is determined to be the read retry condition #5. A passed read retry condition having the second highest success count for the lower page (e.g., a first sub-optimal read retry condition for the lower page) is determined to be the read retry condition #4. That is, for the lower page, the read retry condition #5 is a passed read retry condition recorded with the first highest count (e.g., the first highest count=10) in the 20 passed read retry operations, and the read retry condition #4 is a passed read retry condition recorded with the second highest count (e.g., the second highest count=8) in the 20 passed read retry operations. With respect to the middle page, a passed read retry condition having the first highest success count (e.g., a second optimal read retry condition for the middle page) is the read retry condition #9, and a passed read retry condition having the second highest success count (e.g., a second sub-optimal read retry condition for the middle page) is the read retry condition #8. With respect to the upper page, a passed read retry condition having the first highest success count (e.g., a third optimal read retry condition for the upper page) is the read retry condition #13, and a passed read retry condition having the second highest success count (e.g., a third sub-optimal read retry condition for the upper page) is the read retry condition #10.

As shown in FIG. 10B, a first combined read condition for all of the lower, middle, and upper pages may be generated by combining the first optimal read retry condition for the lower page, the second optimal read retry condition for the middle page, and the third optimal read retry condition for the upper page. For example, with respect to the lower page, a read voltage offset for the read voltage Vrd1 LP and a read voltage offset for the read voltage Vrd5 LP in the first combined read condition can be corresponding read voltage offsets (ΔV5_1, ΔV5_5) from the first optimal read retry condition (read retry condition #5), as illustrated by arrows 1020 and 1022 respectively. With respect to the middle page, a read voltage offset for the read voltage Vrd2 MP, a read voltage offset for the read voltage Vrd4 MP, and a read voltage offset for the read voltage Vrd6 MP in the first combined read condition can be corresponding read voltage offsets (ΔV9_2, ΔV9_4, ΔV9_6) from the second optimal read retry condition (read retry condition #9), as illustrated by arrows 1024, 1026, and 1028 respectively. With respect to the upper page, a read voltage offset for the read voltage Vrd3 UP and a read voltage offset for the read voltage Vrd7 UP in the first combined read condition can be corresponding read voltage offsets (ΔV13_3, ΔV13_7) from the third optimal read retry condition (read retry condition #13), as illustrated by arrows 1030 and 1032 respectively.

As shown in FIG. 10C, a second combined read condition for all of the lower, middle, and upper pages may be generated by combining the first sub-optimal read retry condition for the lower page, the second sub-optimal read retry condition for the middle page, and the third sub-optimal read retry condition for the upper page. For example, with respect to the lower page, a read voltage offset for the read voltage Vrd1 LP and a read voltage offset for the read voltage Vrd5 LP in the second combined read condition can be corresponding read voltage offsets (ΔV4_1, ΔV4_5) from the first sub-optimal read retry condition (read retry condition #4). With respect to the middle page, a read voltage offset for the read voltage Vrd2 MP, a read voltage offset for the read voltage Vrd4 MP, and a read voltage offset for the read voltage Vrd6 MP in the second combined read condition can be corresponding read voltage offsets (ΔV8_2, ΔV8_4, ΔV8_6) from the second sub-optimal read retry condition (read retry condition #8). With respect to the upper page, a read voltage offset for the read voltage Vrd3 UP and a read voltage offset for the read voltage Vrd7 UP in the second combined read condition can be corresponding read voltage offsets (ΔV10_3, ΔV10_7) from the third sub-optimal read retry condition (read retry condition #10). In some implementations, the first combined read condition of FIG. 10B may have a higher ranking than the second combined read condition of FIG. 10C.

An example generation of combined read conditions for a QLC memory device is illustrated in FIGS. 10D-10E. Referring to FIG. 10D, 20 latest passed read retry operations (#1-#20) and their respective passed read retry conditions are recorded. For example, a first passed read retry operation #1 is recorded, which is associated with a first passed read retry condition for the lower page (e.g., read retry condition #5 in a read retry table), a second passed read retry condition for the middle page (e.g., read retry condition #9 in the read retry table), a third passed read retry condition for the upper page (e.g., read retry condition #13 in the read retry table), and a fourth passed read retry condition for the extra page (e.g., read retry condition #10 in the read retry table).

Based on the record of the 20 passed read retry operations, a passed read retry condition having the first highest success count (or the maximal success count) for the lower page (e.g., a first optimal read retry condition for the lower page) is determined to be the read retry condition #5. With respect to the middle page, a passed read retry condition having the first highest success count (e.g., a second optimal read retry condition for the middle page) is the read retry condition #9. With respect to the upper page, a passed read retry condition having the first highest success count (e.g., a third optimal read retry condition for the upper page) is the read retry condition #13. With respect to the extra page, a passed read retry condition having the first highest success count (e.g., a fourth optimal read retry condition for the extra page) is the read retry condition #10.

As shown in FIG. 10E, a combined read condition for all of the lower, middle, upper, and extra pages may be generated by combining the first optimal read retry condition for the lower page, the second optimal read retry condition for the middle page, the third optimal read retry condition for the upper page, and the fourth optimal read retry condition for the extra page, by performing operations like those described above with reference to FIG. 10B. The similar description will not be repeated herein.

Referring back to FIG. 7, method 700 may proceed to operation 706, in which the memory controller may control the memory device to perform a read operation based on the one or more combined read conditions. In some implementations, the memory controller may select a first combined read condition from the one or more combined read conditions, and control the memory device to perform the read operation based on the first combined read condition. For example, the read operation may be performed on a TLC memory cell. The first combined read condition may include read voltage offsets for the read voltages Vrd1-Vrd7, respectively. The memory controller may adjust the read voltages Vrd1-Vrd7 using the corresponding read voltage offsets, and instruct the memory device to perform the read operation with the adjusted read voltages Vrd1-Vrd7.

Responsive to determining that the read operation based on the first combined read condition fails, the memory controller may determine whether a count of the combined read conditions selected to perform the read operation is smaller than a threshold. Responsive to the count of combined read conditions selected to perform the read operation being smaller than the threshold, the memory controller may select a second combined read condition from the one or more combined read conditions. Then, the memory controller may control the memory device to perform the read operation based on the second combined read condition.

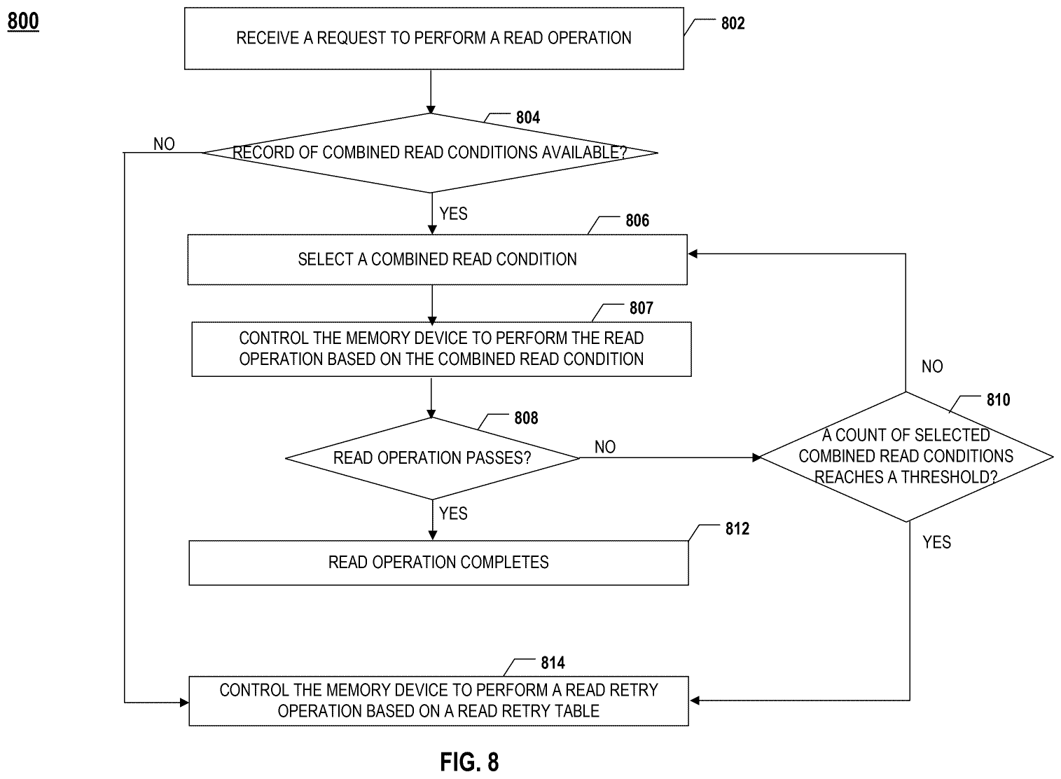

Responsive to determining that the read operation based on the second combined read condition fails, the memory controller may select one or more other combined read conditions to perform the read operation until the count of combined read conditions selected to perform the read operation reaches the threshold or all the pages of the memory cell are read out successfully by the read operation. A detailed method for performing the read operation is illustrated below with reference to FIG. 8.

In some implementations, the memory controller may determine that the read operation on the memory device based on the one or more combined read conditions fails or the count of combined read conditions selected to perform the read operation reaches the threshold. Then, the memory controller may control the memory device to perform a read retry operation based on a read retry table, and update the one or more combined read conditions based on the result of the read retry operation. A detailed method for performing the read retry operation is illustrated below with reference to FIG. 9.

FIG. 8 illustrates a flowchart of another method 800 for operating a memory controller, according to some aspects of the present disclosure. Method 800 may be performed by a memory controller which can be any memory controller disclosed herein, such as memory controller 106 of FIG. 1 or memory controller 300 of FIG. 3. The memory controller can be communicatively coupled to a memory device, such as memory device 104 of FIG. 1 or memory device 302 of FIG. 3. It is understood that the operations shown in method 800 may not be exhaustive and that other operations can be performed as well before, after, or between any of the illustrated operations. Further, some of the operations may be performed simultaneously, or in a different order than shown in FIG. 8.

Method 800 may begin with operation 802, in which the memory controller (e.g., a processor of the memory controller) may receive a request to perform a read operation on a memory cell of a memory device.

Method 800 may proceed to operation 804, in which the memory controller may determine whether a record of combined read conditions is available. For example, the memory controller may determine whether there are any combined read conditions available. Responsive to one or more combined read conditions being available, method 800 may proceed to operation 806. Otherwise, method 800 may proceed to operation 814.

At operation 806, the memory controller may select a combined read condition from the one or more combined read conditions. For example, the memory controller may select a combined read condition from the one or more combined read conditions based on a ranking of the combined read condition among all the combined read conditions. In another example, among all remaining combined read conditions that are not yet selected, the memory controller may select one with the highest ranking among the remaining combined read conditions.

Method 800 may proceed to operation 807, in which the memory controller may control the memory device to perform the read operation on the memory cell based on the combined read condition.

Method 800 may proceed to operation 808, in which the memory controller may determine whether the read operation based on the combined read condition passes. Responsive to the read operation being passed, method 800 may proceed to operation 812. Otherwise, method 800 may proceed to operation 810.

At operation 810, the memory controller may determine whether a count of selected combined read conditions reaches a threshold and there is at least one additional combined read condition to be selected. Responsive to the count of selected combined read conditions being smaller than the threshold and there being at least one additional combined read condition to be selected, method 800 may return back to operation 806 to select another combined read condition to perform the read operation. Otherwise (e.g., responsive to the count of selected combined read conditions reaching the threshold or there being no additional combined read condition to be selected), method 800 may proceed to operation 814.

At operation 812, the memory controller may determine that the read operation completes. For example, the memory controller may determine that the pages of the memory cell are read out successfully using the selected combined read condition. The memory controller may update the record of the combined read conditions responsive to the pages of the memory cell being read out successfully using the selected combined read condition. For example, each combined read condition in the record may be associated with a corresponding ranking. A ranking of the selected combined read condition in the record can be increased since it can be used to read out the pages of the memory cell successfully.

At operation 814, the memory controller may control the memory device to perform a read retry operation based on a read retry table. An example method of performing the read retry operation is illustrated below with reference to FIG. 9.

It is contemplated that compared with FIG. 6 which includes a default read in the beginning of method 600, there is no default read in the beginning of method 800. That is, a read based on a combined read condition in FIG. 8 may replace the default read of FIG. 6.

FIG. 9 illustrates a flowchart of a method 900 for performing a read retry operation based on a read retry table, according to some aspects of the present disclosure. Method 900 may be performed by a memory controller, which can be any memory controller disclosed herein, such as memory controller 106 of FIG. 1 or memory controller 300 of FIG. 3. The memory controller can be communicatively coupled to a memory device, such as memory device 104 of FIG. 1 or memory device 302 of FIG. 3. It is understood that the operations shown in method 900 may not be exhaustive and that other operations can be performed as well before, after, or between any of the illustrated operations. Further, some of the operations may be performed simultaneously, or in a different order than shown in FIG. 9.

Method 900 may begin with operation 902, in which the memory controller (e.g., a processor of the memory controller) may control the memory device to perform a default read on a memory cell based on a default read condition. Operation 902 may be like operation 604 of FIG. 6, and a similar description will not be repeated herein.

Method 900 may proceed to operation 904, in which the memory controller may determine whether the default read passes. Responsive to the default read being passed, method 900 ends. Otherwise, method 900 may proceed to operation 906. Operation 904 may be like operation 606 of FIG. 6, and a similar description will not be repeated herein.

At operation 906, the memory controller may select a page to be read. Operation 906 may be like operation 608 of FIG. 6, and the similar description will not be repeated herein.

Method 900 may proceed to operation 908, in which the memory controller may select a read retry condition from a read retry table based on a sticky retry order. Operation 908 may be like operation 610 of FIG. 6, and a similar description will not be repeated herein.

Method 900 may proceed to operation 910 in which the memory controller may control the memory device to perform a retry read for the page based on the selected read retry condition. Operation 910 may be like operation 612 of FIG. 6, and a similar description will not be repeated herein.

Method 900 may proceed to operation 912, in which the memory controller may determine whether the retry read (which reads the selected page of the memory cell) passes. If the retry read passes, method 900 may proceed to operation 920. Otherwise, method 900 may proceed to operation 914. Operation 912 may be like operation 614 of FIG. 6, and a similar description will not be repeated herein.

At operation 914 (when the retry read at operation 912 fails), the memory controller may determine whether there is an additional read retry condition to be selected from the read retry table. If there is an additional read retry condition to be selected, method 900 may proceed to operation 916. Otherwise (e.g., there is no additional read retry condition to be selected, or equivalently, all the read retry conditions in the read retry table are already selected and fail in the retry read), method 900 may proceed to operation 918, which indicates that the read retry operation fails. Operation 914 may be like operation 616 of FIG. 6, and a similar description will not be repeated herein.

At operation 916, the memory controller may select the next read retry condition from the read retry table. Operation 916 may be like operation 618 of FIG. 6, and a similar description will not be repeated herein.

At operation 920, the memory controller may update the sticky retry order to be an identifier of the read retry condition that reads out the page successfully. Operation 920 may be like operation 622 of FIG. 6, and a similar description will not be repeated herein.

Method 900 may proceed to operation 922, in which the memory controller may record the read retry condition as a passed read retry condition for the page.

Method 900 may proceed to operation 924, in which the memory controller may determine whether there is an additional page to be read. Responsive to determining that there is at least an additional page to be read, method 900 may proceed to operation 926. Otherwise (e.g., all the pages are already read successfully), method 900 may proceed to operation 928. Operation 924 may be like operation 624 of FIG. 6, and a similar description will not be repeated herein.

At operation 926, the memory controller may select another page to be read. Operation 926 may be like operation 626 of FIG. 6, and a similar description will not be repeated herein.

At operation 928, the memory controller may determine that the read retry operation passes. In this case, the pages are read out successfully for the memory cell, and the read retry operation may be referred to as a passed read retry operation. Operation 928 may be like operation 628 of FIG. 6, and a similar description will not be repeated herein.

Method 900 may proceed to operation 930 in which the memory controller may update a record of the combined read conditions. For example, records like those of FIGS. 10A-10E can be updated based on the newly passed read retry operation and its passed read retry conditions.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory system, comprising:
a non-volatile memory device configured to store data; and
a memory controller coupled to the non-volatile memory device and configured to:
determine one or more combined read conditions based on passed read retry conditions associated with historical read retry operations; and
control the non-volatile memory device to perform a read operation based on the one or more combined read conditions.

2. The memory system of claim 1, wherein the historical read retry operations comprise passed read retry operations each of which reads out corresponding data from the non-volatile memory device successfully using at least one of the passed read retry conditions.

3. The memory system of claim 1, wherein the non-volatile memory device comprises memory cells, and each of the memory cells is configured to store at least two bits, the at least two bits respectively corresponding to at least two pages.

4. The memory system of claim 3, wherein the memory controller is further configured to record the passed read retry conditions associated with the historical read retry operations.

5. The memory system of claim 4, wherein to record the passed read retry conditions associated with the historical read retry operations, the memory controller is further configured to:
record one or more passed read retry conditions for each historical read retry operation, wherein each of the one or more passed read retry conditions comprises a read retry condition from a read retry table and is used to read out at least one of the at least two pages successfully in the historical read retry operation.

6. The memory system of claim 5, wherein:
the at least two pages comprise at least a first page and a second page;
the one or more passed read retry conditions comprise a first passed read retry condition for the first page and a second passed read retry condition for the second page;
the first passed read retry condition comprises one or more first read parameters used to read out the first page successfully in the historical read retry operation; and
the second passed read retry condition comprises one or more second read parameters used to read out the second page successfully in the historical read retry operation.

7. The memory system of claim 6, wherein each of the one or more first read parameters and the one or more second read parameters comprises a read voltage or a read voltage offset.

8. The memory system of claim 3, wherein the one or more combined read conditions comprise a first combined read condition, and to determine the one or more combined read conditions, the memory controller is further configured to:
determine optimal read retry conditions for the at least two pages, respectively, at least by:
for each page from the at least two pages, determining an optimal read retry condition from the passed read retry conditions, wherein the optimal read retry condition comprises a passed read retry condition having a first highest success count to read out the page in the historical read retry operations; and
combine the optimal read retry conditions to generate the first combined read condition based on the at least two pages.

9. The memory system of claim 8, wherein:
the at least two pages comprise at least a first page and a second page;
the optimal read retry conditions comprise a first optimal read retry condition for the first page and a second optimal read retry condition for the second page; and
the first combined read condition comprises one or more first read parameters from the first optimal read retry condition for the first page and one or more second read parameters from the second optimal read retry condition for the second page.

10. The memory system of claim 8, wherein the one or more combined read conditions further comprise a second combined read condition, and to determine the one or more combined read conditions, the memory controller is further configured to:
determine sub-optimal read retry conditions for the at least two pages, respectively, at least by:
for each page from the at least two pages, determining a sub-optimal read retry condition from the passed read retry conditions, wherein the sub-optimal read retry condition comprises a passed read retry condition having a second highest success count to read out the page in the historical read retry operations; and
combine the sub-optimal read retry conditions to generate the second combined read condition based on the at least two pages.

11. The memory system of claim 1, wherein to control the non-volatile memory device to perform the read operation based on the one or more combined read conditions, the memory controller is further configured to:
select a first combined read condition from the one or more combined read conditions; and
control the non-volatile memory device to perform the read operation based on the first combined read condition.

12. The memory system of claim 11, wherein the memory controller is further configured to:
determine that the read operation based on the first combined read condition fails;
determine that a count of combined read conditions selected to perform the read operation is smaller than a threshold;
select a second combined read condition from the one or more combined read conditions; and
control the non-volatile memory device to perform the read operation based on the second combined read condition.

13. The memory system of claim 1, wherein the memory controller is further configured to:
determine that the read operation on the non-volatile memory device based on the one or more combined read conditions fails or a count of combined read conditions selected to perform the read operation reaches a threshold;
control the non-volatile memory device to perform a read retry operation based on a read retry table; and
update the one or more combined read conditions based on a result of the read retry operation.

14. The memory system of claim 1, wherein the memory controller is further configured to store the one or more combined read conditions in the non-volatile memory device responsive to power off.

15. The memory system of claim 3, wherein each of the one or more combined read conditions comprises read parameters from at least two different passed read retry conditions.

16. The memory system of claim 15, wherein the at least two pages comprise a first page and a second page, and each of the one or more combined read conditions comprises:
one or more read parameters from a first one of the passed read retry conditions for the first page; and
one or more read parameters from a second one of the passed read retry conditions for the second page.

17. A memory controller, comprising:
a memory configured to store instructions; and
a processor coupled to the memory and configured to execute the instructions to perform a process comprising:
determining one or more combined read conditions based on passed read retry conditions associated with historical read retry operations on a non-volatile memory device; and
controlling the non-volatile memory device to perform a read operation based on the one or more combined read conditions.

18. A method of operating a memory controller, comprising:
determining one or more combined read conditions based on passed read retry conditions associated with historical read retry operations on a non-volatile memory device; and
controlling the non-volatile memory device to perform a read operation based on the one or more combined read conditions.

19. The method of claim 18, wherein the non-volatile memory device comprises memory cells, and each of the memory cells is configured to store at least two bits, the at least two bits respectively corresponding to at least two pages.

20. The method of claim 19, wherein the one or more combined read conditions comprise a first combined read condition, and determining the one or more combined read conditions comprises:
determining optimal read retry conditions for the at least two pages, respectively, at least by:
for each page from the at least two pages, determining an optimal read retry condition from the passed read retry conditions, wherein the optimal read retry condition comprises a passed read retry condition having a first highest success count to read out the page in the historical read retry operations; and
combining the optimal read retry conditions to generate the first combined read condition based on the at least two pages.
